(19) United States
(12) Patent Application Publication
(10) Pub. No.: US 2020/0395232 A1
(43) Pub. Date: Dec. 17, 2020

(54) SUBSTRATE PROCESS APPARATUS

(71) Applicant: BROOKS AUTOMATION, INC., Chelmsford, MA (US)

(72) Inventors: Alexander Krupyshev, Chelmsford, MA (US); Leigh Sharrock, Londonberry, NH (US); Daniel Babbs, Austin, TX (US); Robert May, Austin, TX (US)

(21) Appl. No.: 16/899,151

(22) Filed: Jun. 11, 2020

Related U.S. Application Data
(60) Provisional application No. 62/861,543, filed on Jun. 14, 2019.

(51) Int. Cl. H01L 21/67; H01L 21/677

(52) U.S. Cl. CPC H01L 21/67201; H01L 21/67126; H01L 21/67742

(57) ABSTRACT

A process apparatus including a front end with a load opening for loading production workpieces into the apparatus; a process section being offset at a distance from and coupled to the front end via an interior transport path configured for transport of the workpieces between the front end and process section; a load lock between the front end and process section with the transport path extending through the load lock, the load lock having an intermediate entry with an opening shunting the transport path to the exterior separate from the front end; and a predetermined interchangeable transport carrier cassette configured to be entered within the load lock from the exterior through the intermediate entry opening, the entry and removal of the cassette through the opening loads and unloads the load lock with a transport path interface that interfaces, the transport path coincident with the cassette loaded in the load lock.

### CROSS-REFERENCE TO RELATED APPLICATIONS

This application is a non-provisional of and claims the benefit of U.S. provisional patent No. 62/861,543, filed on Jun. 14, 2019, the disclosure of which is incorporated herein in its entirety.

### BACKGROUND

### 1. Field

The exemplary embodiments generally relate to controlled atmosphere environments and, more particularly, to increasing throughput in those environments.

### 2. Brief Description of Related Developments

Increased efficiencies are sought in the production of electronics, and particularly in the production of semiconductor devices that form an ever increasing part of the electronics. Generally, semiconductor substrate processing systems include a transfer chamber to which processing modules and an atmospheric interface are coupled. To increase the efficiency (e.g., to extend production time between maintenance) a trend in semiconductor substrate processing includes the employment of serviceable parts that are introduced into the processing modules. The use of these serviceable parts may increase or prolong a time between extensive maintenance procedures of at least the processing modules (e.g., the time between long interval process chamber cleanings, when extensive maintenance is performed, may be prolonged).

Generally, the atmospheric interface of the semiconductor substrate processing systems typically includes one or more substrate holding location such as, for example, load locks that have fixed support structure for supporting a semiconductor substrate that is transferred into the load lock from a substrate holding cassette or atmospheric front end module. The support structure for the semiconductor substrate within the substrate holding location and throughout the semiconductor processing systems is specifically configured for a predetermined shape and size of the semiconductor substrate to be held thereby and processed by the processing modules coupled to the transfer chamber. The configuration of the substrate processing systems and their components typically provides for the serviceable parts being introduced into the processing modules by breaking a vacuum of the semiconductor substrate processing system for inserting the serviceable parts directly to the processing modules (e.g., physically opening a process module to insert the consumable materials). Breaking the vacuum of the semiconductor substrate processing systems leads to increased downtime and maintenance costs of the semiconductor substrate processing systems associated with at least the pumping and venting (e.g., cycling of the internal atmosphere) of the semiconductor substrate processing systems. Breaking the vacuum also typically means that the process must be requalified before actual production can begin again, which also increases the downtime and maintenance costs. A series of substrates will need to be run though and tested to verify the process is working as it did before the vacuum of the semiconductor substrate processing system was broken.

### BRIEF DESCRIPTION OF THE DRAWINGS

The foregoing aspects and other features of the disclosed embodiment are explained in the following description, taken in connection with the accompanying drawings, wherein:

FIGS. 1A-1F are schematic illustrations of exemplary process apparatus incorporating aspects of the present disclosure;

FIGS. 2A-2E are schematic illustrations of exemplary substrate transports in accordance with aspects of the present disclosure;

FIGS. 3A and 3B are schematic illustrations of a chamber of the process apparatus of FIGS. 1A-1F incorporating aspects of the present disclosure;

FIGS. 3C and 3D are schematic illustrations of portions of the chamber of FIGS. 3A and 3B in accordance with aspects of the present disclosure;

FIG. 4 is a schematic illustration of the chamber of FIGS. 3A and 3B in accordance with aspects of the present disclosure;

FIGS. 5A-5F are schematic illustrations of portions of the chamber of FIGS. 3A and 3B in accordance with aspects of the present disclosure;

FIGS. 6A-6F are schematic illustrations of portions of the chamber of FIGS. 3A and 3B in accordance with aspects of the present disclosure;

FIG. 7 is a schematic illustration of the chamber of FIGS. 3A and 3B in accordance with aspects of the present disclosure;

FIGS. 8A-8C are schematic illustrations of portions of the chamber of FIGS. 3A and 3B in accordance with aspects of the present disclosure;

FIGS. 9A and 9B are schematic illustrations of portions of the chamber of FIGS. 3A and 3B in accordance with aspects of the present disclosure;

FIGS. 10A-10C are schematic illustrations of portions of the chamber of FIGS. 3A and 3B in accordance with aspects of the present disclosure;

FIGS. 11A-11D are schematic illustrations of portions of the chamber of FIGS. 3A and 3B in accordance with aspects of the present disclosure;

FIG. 12 is a schematic illustration of a portion of the chamber of FIGS. 3A and 3B in accordance with aspects of the present disclosure;

FIG. 13 is a block diagram of a portion of the lok chamber of FIGS. 3A and 3B in accordance with aspects of the present disclosure;

FIG. 14 is a block diagram of a method in accordance with aspects of the present disclosure; and

FIG. 15 is a schematic illustration of a portion of the chamber in FIGS. 3A and 3B in accordance aspects of the present disclosure.

### DETAILED DESCRIPTION

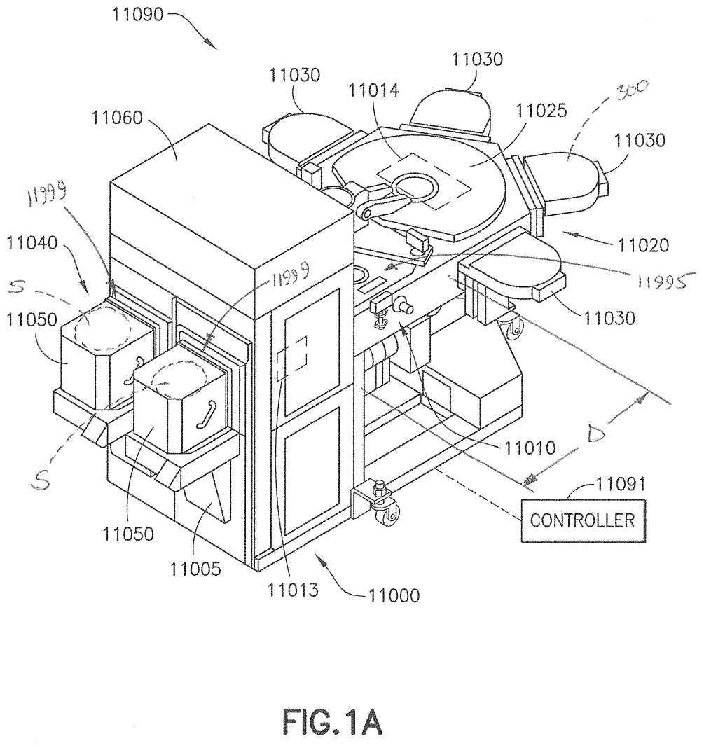

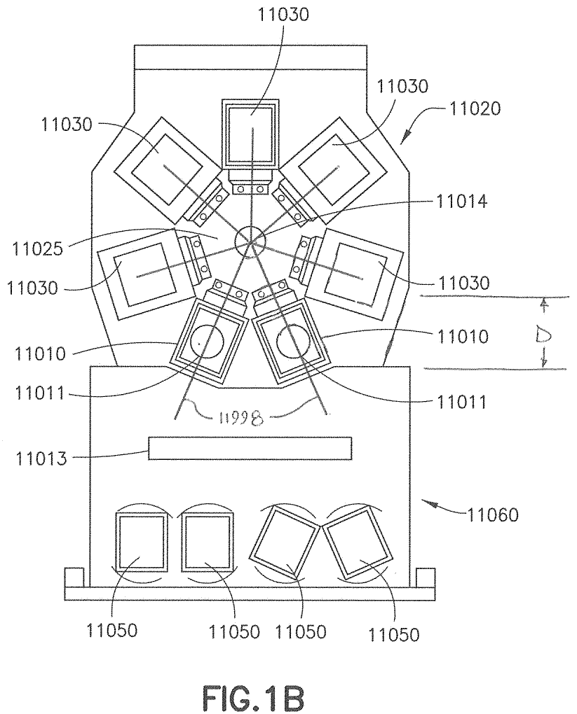

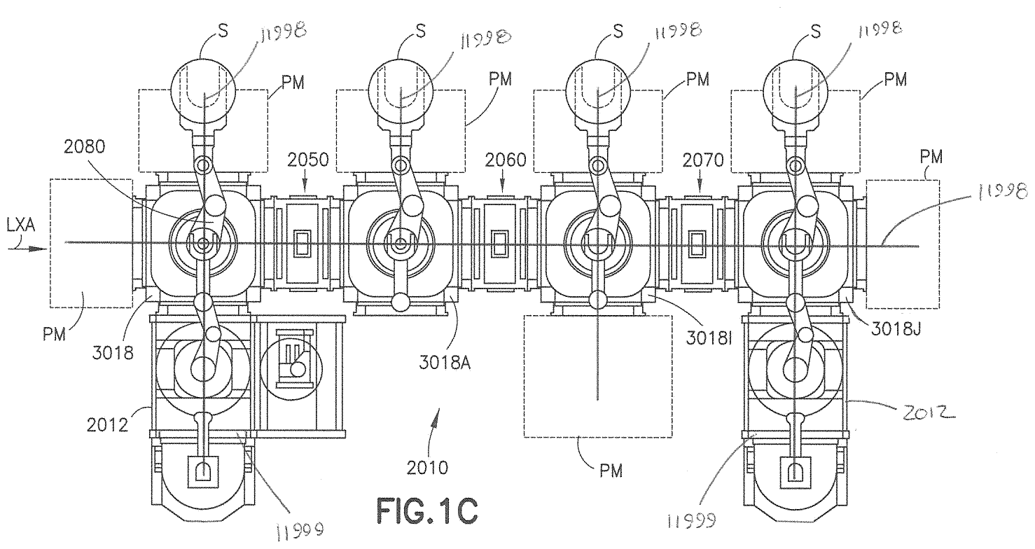

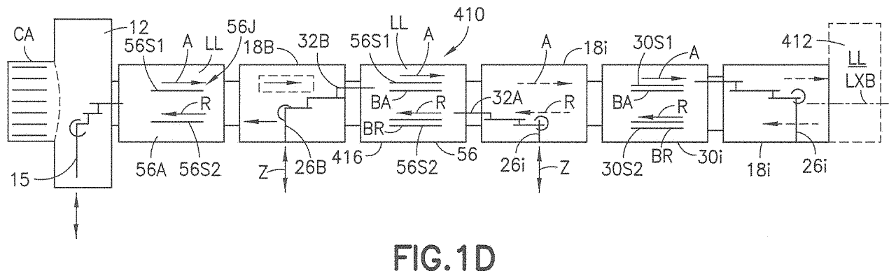

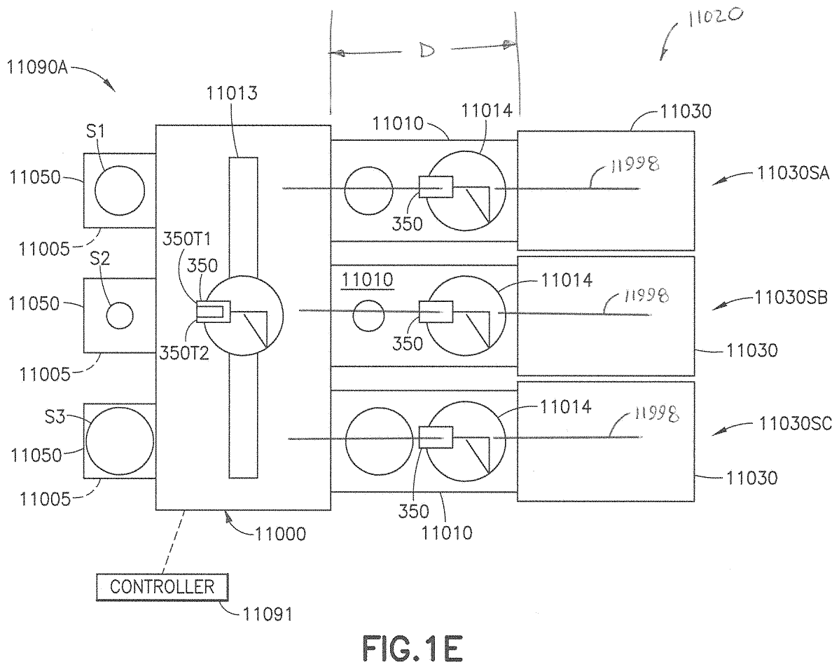

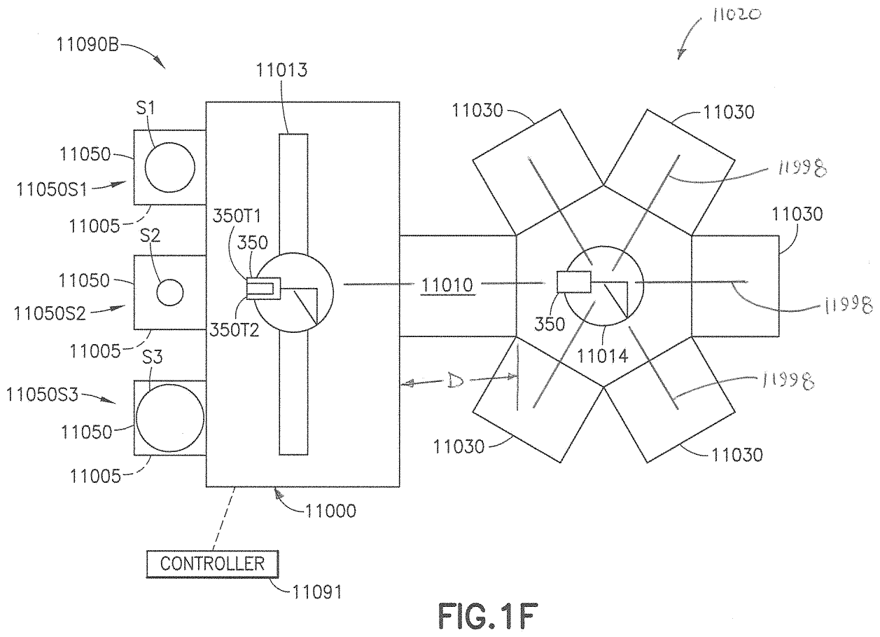

FIGS. 1A-1F illustrate exemplary semiconductor substrate processing systems/apparatus in accordance with aspects of the present disclosure. Although the aspects of the present disclosure will be described with reference to the drawings, it should be understood that the aspects of the present disclosure can be embodied in many forms. In addition, any suitable size, shape or type of elements or materials could be used.

The aspects of the present disclosure provide for a reconfigurable substrate holding location that may be employed to introduce and/or change temporal features and/or structures such as to introduce non-production materials (which may have a different physical form factor, i.e., shape, size, weight, etc. than a semiconductor substrate) into a semiconductor substrate processing system substantially without breaking a vacuum atmosphere of a vacuum back end of the semiconductor substrate processing system. The aspects of the present disclosure provide for a substrate holding location that includes interchangeable transport carrier cassettes that may be inserted and removed from the substrate holding location. At least one of the interchangeable transport carrier cassettes is configured to hold an item of non-production material that can be inserted into the substrate holding location, with the item of non-production material thereon, without breaking the vacuum atmosphere of the semiconductor substrate processing system. The item of non-production material may then be transported to a desired location, such as a processing module, by a substrate transport apparatus of the semiconductor substrate processing system within a processing environment (e.g., vacuum or other suitable environment). The aspects of the present disclosure provide for decreased downtime of the semiconductor substrate processing system such that only a small volume (e.g., compared to a volume of the transfer chamber and process module(s) coupled thereto) of the substrate holding locations into which the interchangeable carriers are inserted are cycled between atmospheric conditions and vacuum atmospheres. The aspects of the present disclosure may also provide for the introduction of the non-production materials during short interval process periodic maintenance (e.g., when minor maintenance is performed) of the semiconductor substrate processing system.

It is noted that while the aspects of the present disclosure are described herein with respect to a load lock, the aspects of the present disclosure may be applied equally to any suitable load lock used for transferring “production” substrates within the semiconductor processing system, a load lock dedicated to the introduction and removal of non-production material to/from the semiconductor processing system, and/or to a vacuum or atmospheric transport chamber.

Referring to FIGS. 1A and 1B, a substrate processing apparatus 11090 (also referred to herein as a substrate processing system or tool), such as for example a semiconductor tool station is shown in accordance with aspects of the disclosed embodiment. Although a semiconductor tool station is shown in the drawings, the aspects of the disclosed embodiment described herein can be applied to any tool station or application employing robotic manipulators. In this example the substrate processing apparatus 11090 is shown as a cluster tool, however the aspects of the disclosed embodiment may be applied to any suitable tool station such as, for example, a linear tool station such as that shown in FIGS. 1C and 1D and described in U.S. Pat. No. 8,398,355, entitled “Linearly Distributed Semiconductor Workpiece Processing Tool,” issued Mar. 19, 2013, the disclosure of which is incorporated by reference herein in its entirety.

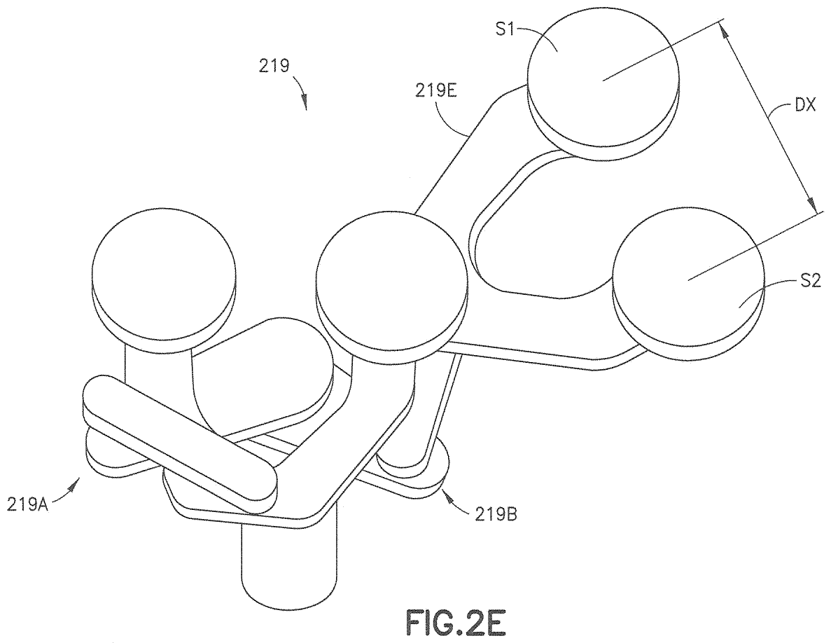

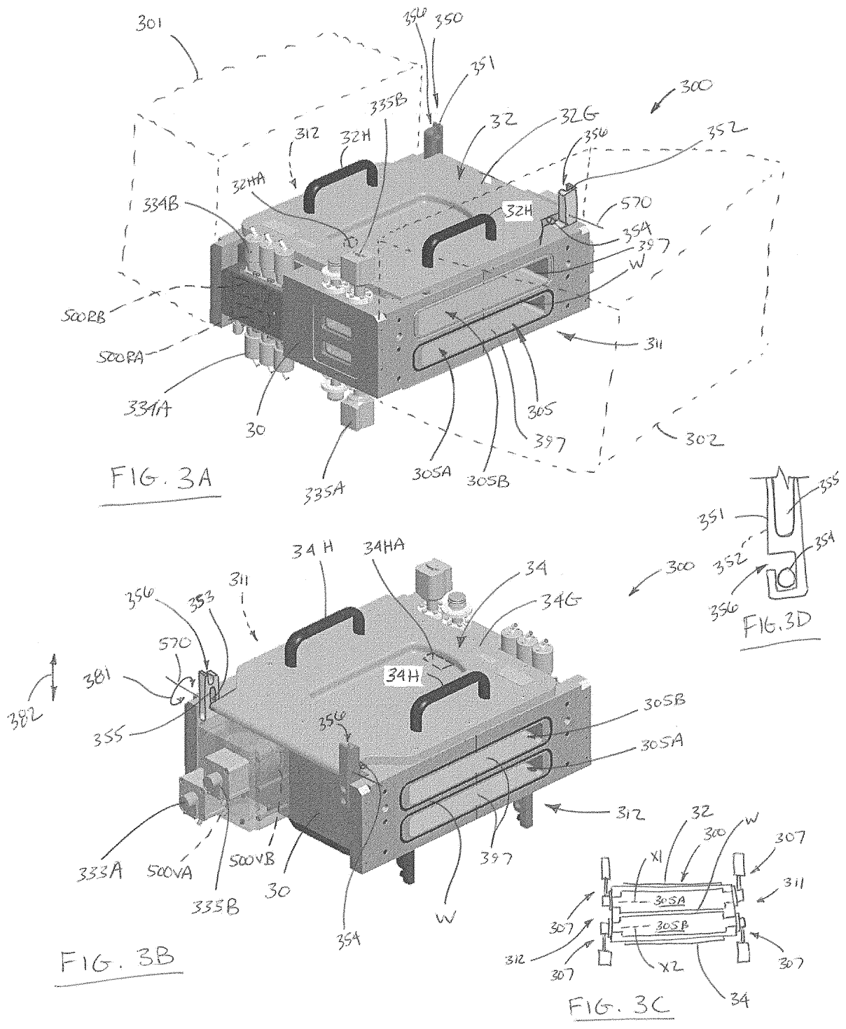

The substrate processing apparatus 11090 generally includes an atmospheric front end 11000 (also referred to herein as a workpiece load chamber), a vacuum load lock 11010 (referred to generally herein as a load lock), and a vacuum back end 11020 (also referred to herein as a process section). In other aspects, the substrate processing apparatus 11090 may have any suitable configuration. It is noted that while the aspects of the present disclosure are described herein with respect to a load lock (see for example load lock 300 in, e.g., FIG. 3) for exemplary purposes only, the aspects of the disclosed embodiment may be applied to any suitable chamber of any suitable processing apparatus (such as those described with respect to FIGS. 1A-1F or any other suitable processing apparatus), where the chamber may be one or more of a metrology chamber, a load lock chamber, an inspection station, an aligner station, a buffer station, transport chamber, or any other suitable substrate holding area whose atmosphere may be selectably isolated (e.g., a lock chamber) from other portions of the processing apparatus (see FIGS. 1C and 1D described below).

The components of each of the atmospheric front end 11000, vacuum load lock 11010, and vacuum back end 11020 may be connected to a controller 11091 which may be part of any suitable control architecture such as, for example, a clustered architecture control. The control system may be a closed loop controller having a master controller, cluster controllers and autonomous remote controllers such as those disclosed in U.S. Pat. No. 7,904,182 entitled “Scalable Motion Control System” issued on Mar. 8, 2011 the disclosure of which is incorporated herein by reference in its entirety. In other aspects, any suitable controller and/or control system may be utilized. The controller 11091 includes any suitable memory and processor(s) that include non-transitory program code for operating the substrate processing apparatus 11090 to effect handling of substrates S (see FIG. 1C) as described herein. The controller 11091 is configured to determine the location of the substrate relative to the end effector and/or the substrate holding station to effect picking and placing of the substrates S (FIG. 1C). In one aspect, the controller 11091 is configured to receive detection signals corresponding to one or more features of the end effector and/or transport arm of a substrate transport apparatus/robot and determine the location of the substrate relative to the end effector and/or the substrate holding station to effect picking and placing of the substrates and/or a position of one or more end effector tines.

In one aspect, the atmospheric front end 11000 generally includes load port modules 11005 and a mini-environment 11060 such as for example an equipment front end module (EFEM). The load port modules 11005 each form a load opening 11999 for loading, from an exterior of the substrate processing apparatus 11090, production substrates (also referred to herein as workpieces) into the substrate processing apparatus 11090. The load port modules 11005 may be box opener/loader to tool standard (BOLTS) interfaces that conform to SEMI standards E15.1, E47.1, E62, E19.5 or E1.9 for 300 mm load ports, front opening or bottom opening boxes/pods and cassettes. In other aspects, the load port modules 11005 may be configured as 200 mm substrate interfaces or 450 mm substrate interfaces or any other suitable substrate interfaces such as for example larger or smaller substrates or flat panels for flat panel displays. Although two load port modules 11005 are shown in FIG. 1A, in other aspects any suitable number of load port modules 11005 may be incorporated into the atmospheric front end 11000. The load port modules 11005 may be configured to receive substrate carriers or cassettes 11050 from an overhead transport system, automatic guided vehicles, person guided vehicles, rail guided vehicles or from any other suitable transport method. The load port modules 11005 may interface with the mini-environment 11060 through load ports 11040. In one aspect the load ports 11040 allow the passage of substrates between the substrate cassettes 11050 and the mini-environment 11060.

In one aspect, the mini-environment 11060 generally includes any suitable substrate transport apparatus 11013 that incorporates one or more aspects of the disclosed embodiment described herein. In one aspect the substrate transport apparatus 11013 may be a track mounted robot such as that described in, for example, U.S. Pat. No. 6,002,840, the disclosure of which is incorporated by reference herein in its entirety or in other aspects, any other suitable substrate transport apparatus 11013 having any suitable configuration. The mini-environment 11060 may provide a controlled, clean zone for substrate transfer between multiple load port modules and the vacuum back end 11020.

The vacuum back end or process section 11020 has a process environment arranged for processing the production workpieces S (e.g., which may include a wafer or other substrate which comprises a product of the processing system). The vacuum back end 11020 is offset at a distance D (generally shown in FIGS. 1A, 1B, 1E, and 1F) from the atmospheric front end 11000. The vacuum back end 11020 is coupled to the atmospheric front end 11000 via an interior transport path 11998 (shown generally in FIGS. 1B and 1C) configured at least for transport of the production substrates S between the atmospheric front end 11000 and the vacuum back end 11020. The vacuum back end 11020 generally includes a transport chamber 11025, one or more processing station(s) or module(s) 11030 and any suitable transport robot or apparatus 11014. The substrate transport apparatus 11014 will be described below and may be located within the transport chamber 11025 to transport substrates between the vacuum load lock 11010 and the various processing stations 11030. The processing stations 11030 may operate on the substrates through various deposition, etching, or other types of processes to form electrical circuitry or other desired structure on the substrates. Typical processes include but are not limited to thin film processes that use a vacuum such as plasma etch or other etching processes, chemical vapor deposition (CVD), plasma vapor deposition (PVD), implantation such as ion implantation, metrology, rapid thermal processing (RTP), dry strip atomic layer deposition (ALD), oxidation/diffusion, forming of nitrides, vacuum lithography, epitaxy (EPI), wire bonder and evaporation or other thin film processes that use vacuum pressures. The processing stations 11030 are connected to the transport chamber 11025 to allow substrates to be passed from the transport chamber 11025 to the processing stations 11030 and vice versa. In one aspect the load port modules 11005 and load ports 11040 are substantially directly coupled to the vacuum back end 11020 so that a cassette 11050 mounted on the load port interfaces substantially directly (e.g. in one aspect at least the mini-environment 11060 is omitted while in other aspects the vacuum load lock 11010 is also omitted such that the cassette 11050 is pumped down to vacuum in a manner similar to that of the vacuum load lock 11010) with a vacuum environment of the transfer chamber 11025 and/or a processing vacuum of a processing station 11030 (e.g. the processing vacuum and/or vacuum environment extends between and is common between the processing station 11030 and the cassette 11050).

The vacuum load lock 11010 is located between the atmospheric front end 11000 and the vacuum back end 11020 with the interior transport path 11998 extending through the load lock 11010. For example, the vacuum load lock 11010 may be located between and connected to both the mini-environment 11060 and the vacuum back end 11020. It is noted that the term vacuum as used herein may denote a high vacuum such as 10⁻⁵ Torr or below in which the substrates are processed. The load lock 11010 has, in the distance D offsetting the vacuum back end 11020 from the atmospheric front end 11000, an intermediate entry 11995 (see FIGS. 1A, 4A, and 7) with an opening 666, 667 shunting the interior transport path 11998 to the exterior separate from the atmospheric front end 11000 (e.g., providing an entry/exit to the substrate processing apparatus between the atmospheric front end 11000 and the vacuum back end 11020 that is separate from substrate entry opening(s) of the atmospheric front end 11000). The vacuum load lock 11010 generally includes atmospheric and vacuum slot valves 307 (see, e.g., FIG. 3C). The slot valves 307 may provide the environmental isolation employed to evacuate the load lock 11010 after loading a substrate from the atmospheric front end 11000 and to maintain the vacuum in the transport chamber 11025 when venting the load lock 11010 with an inert gas such as nitrogen. In one aspect, the load lock 11010 includes an aligner 11011 for aligning a fiducial of the substrate to a desired position for processing. In other aspects, the vacuum load lock 11010 may be located in any suitable location of the substrate processing apparatus 11090 and have any suitable configuration and/or metrology equipment.

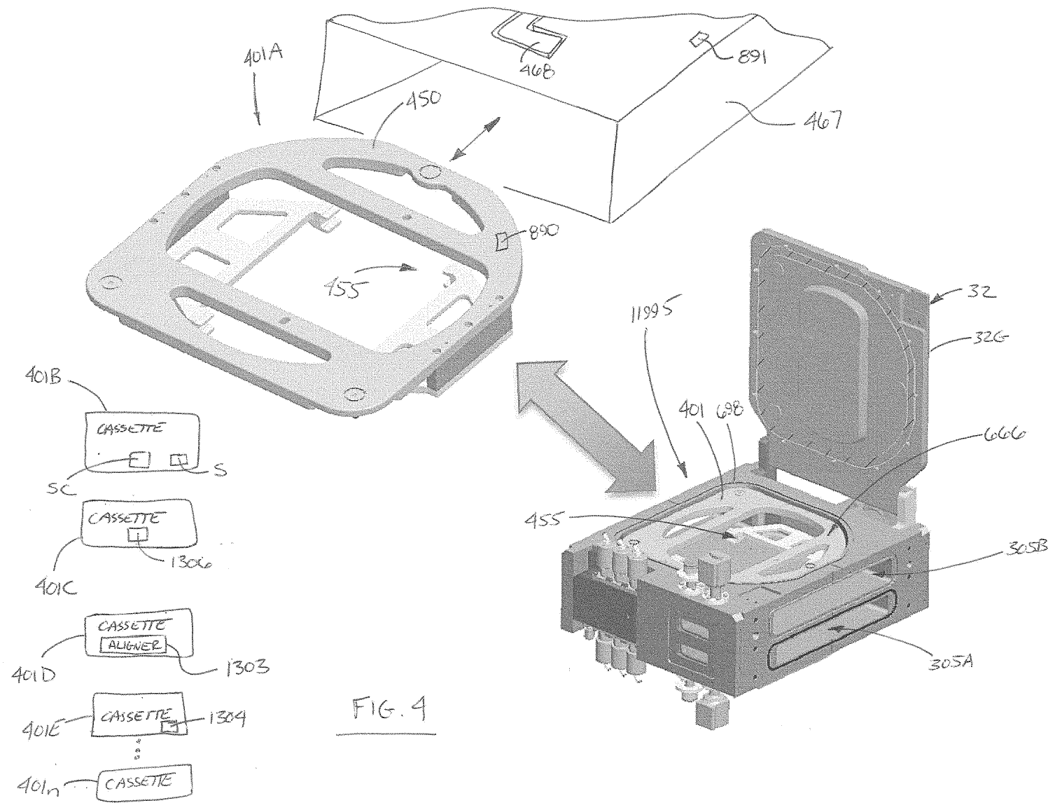

As will be described herein, the aspects of the present disclosure provide for an interchangeable transport carrier cassette 401 (see FIG. 4, and generally referred to herein as transport carrier cassette 401), having an interchangeable cassette frame 450 (see FIG. 4), configured so as to be entered within the load lock 11010 from the exterior through the intermediate entry 11995 opening 666, 667. The entry and removal of the transport carrier cassette 401 through the intermediate entry 11995 opening 666, 667 loads and unloads the load lock 11010 with a transport path interface 455 (as will be described in greater detail herein) that interfaces, in the load lock 11010, the interior transport path 11998. As will be described herein, the transport path interface 455 is a non-production workpiece process component coupled to the interchangeable cassette frame 450 and carried by the transport carrier cassette 401 so as to transport the transport path interface 455 to and from the substrate process apparatus 11090 and repeatably position, on loading of the load lock 11010 through the intermediate entry 11995 opening 666, 667, the transport path interface 455 relative to a transport plane X1, X2 (see FIG. 3C) of the interior transport path 11998 so as to effect interface with the interior transport path 11998 with the transport path interface 455 at the repeatable position. Here, the load lock 11010 has a selectable configuration selectable through the intermediate entry 11995 opening 666, 667 between different predetermined configurations (that are temporal) each having a different (temporal) non-production workpiece process component (e.g., different shelf configurations, processing equipment, etc.) within the load lock 11010. The term “temporal” here is used to denote that the predetermined features are of a temporary nature, added and/or removed (as will be further described herein) to the lock chamber, via access openings, with the lock chamber installed in a process apparatus and without substantial disassembly. The selectable configuration of the load lock 11010 is effected with loading of at least one transport carrier cassette 401, carrying one of the different non-production workpiece process components, through the intermediate entry 11995 opening 666, 667 into the load lock 11010.

Referring now to FIG. 1C, a schematic plan view of a linear substrate processing system 2010 is shown where a tool interface section 2012 (which in this aspect may be configured as a load lock substantially similar to those described herein) is mounted to a transport chamber module 3018 so that the tool interface section 2012 is facing generally towards (e.g. inwards) but is offset from a longitudinal axis LXA of the transport chamber module 3018. The transport chamber module 3018 may be extended in any suitable direction by attaching other transport chamber modules 3018A, 3018I, 3018J to interfaces 2050, 2060, 2070 as described in U.S. Pat. No. 8,398,355, previously incorporated herein by reference. Each transport chamber module 3018, 3018A, 3018I, 3018J includes any suitable substrate transport 2080, which may include one or more aspects of the disclosed embodiment described herein, for transporting substrates S throughout the linear substrate processing system 2010 and into and out of, for example, processing modules PM (which in one aspect are substantially similar to processing stations 11030 described above). As may be realized, each transport chamber module 3018, 3018A, 3018I, 3018J may be capable of holding an isolated or controlled atmosphere (e.g. N2, clean air, vacuum) and operate as a load lock including the aspects of the present disclosure described herein.

Referring to FIG. 1D, there is shown a schematic elevation view of an exemplary processing tool 410 such as may be taken along longitudinal axis LXB of a linear transport chamber 416. In the aspect of the disclosed embodiment shown in FIG. 1D, tool interface section 12 (which in this aspect may be an atmospheric front end) may be representatively connected to the linear transport chamber 416. In this aspect, tool interface section 12 may define one end of the linear transport chamber 416. As seen in FIG. 1D, the linear transport chamber 416 may have another substrate entry/exit station 412 for example at an opposite end from tool interface station 12. In other aspects, other entry/exit stations for inserting/removing substrates from the linear transport chamber 416 may be provided. In one aspect, tool interface section 12 and substrate entry/exit station 412 may allow loading and unloading of substrates from the processing tool 410. In other aspects, substrate may be loaded into the processing tool 410 from one end and removed from the other end. In one aspect, the linear transport chamber 416 may have one or more transfer chamber module(s) 18B, 18i. Each transfer chamber module 18B, 18i may be capable of holding an isolated or controlled atmosphere (e.g. N2, clean air, vacuum). As noted before, the configuration/arrangement of the transport chamber modules 18B, 18i, chambers 56A, 56 (where one or more of chambers 56A, 56 may a metrology chamber, a load lock chamber, an inspection station, an aligner station, a buffer station, or any other suitable substrate holding area whose atmosphere may be selectably isolated (e.g., lock chamber) from other portions of the processing apparatus) and substrate stations forming the linear transport chamber 416 shown in FIG. 1D is merely exemplary, and in other aspects the transport chamber may have more or fewer modules disposed in any desired modular arrangement. In the aspect shown, substrate entry/exit station 412 may be a load lock. In other aspects, a load lock module may be located between the end entry/exit station (similar to substrate entry/exit station 412) or the adjoining transport chamber module (similar to module 18i) may be configured to operate as a load lock.

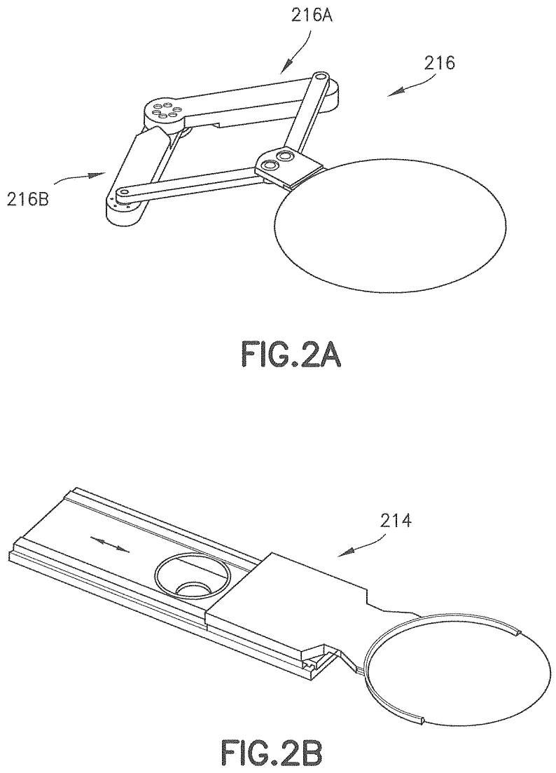

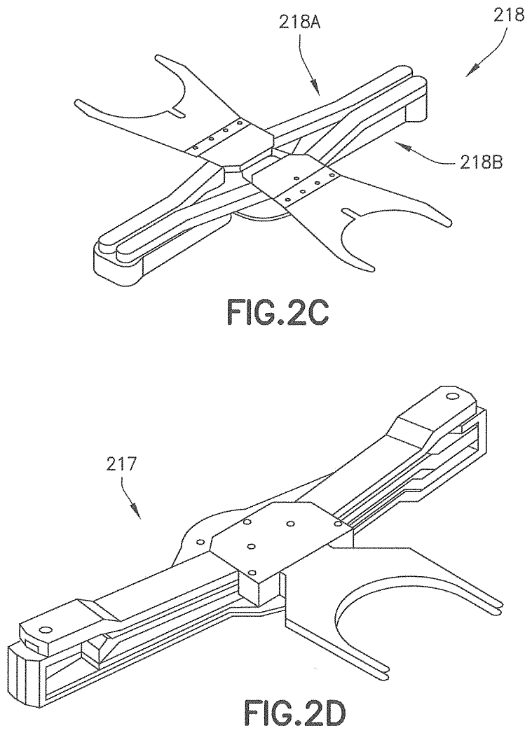

As also noted before, transport chamber modules 18B, 18i have one or more corresponding substrate transport apparatus 26B, 26i, which may include one or more aspects of the disclosed embodiment described herein, located therein. The substrate transport apparatus 26B, 26i of the respective transport chamber modules 18B, 18i may cooperate to provide the linearly distributed substrate transport system in the linear transport chamber 416. In this aspect, the substrate transport apparatus 26B, 26i (which may be substantially similar to the substrate transport apparatus 11013, 11014 of the cluster tool illustrated in FIGS. 1A and 1B) may have a general SCARA arm configuration (though in other aspects the substrate transport apparatus may have any other desired arrangement such as, for example, a linearly sliding arm 214 as shown in FIG. 2B or other suitable arms having any suitable arm linkage mechanisms. Suitable examples of arm linkage mechanisms can be found in, for example, U.S. Pat. No. 7,578,649 issued Aug. 25, 2009, U.S. Pat. No. 5,794,487 issued Aug. 18, 1998, U.S. Pat. No. 7,946,800 issued May 24, 2011, U.S. Pat. No. 6,485,250 issued Nov. 26, 2002, U.S. Pat. No. 7,891,935 issued Feb. 22, 2011, U.S. Pat. No. 8,419,341 issued Apr. 16, 2013 and U.S. patent application Ser. No. 13/293,717 entitled “Dual Arm Robot” and filed on Nov. 10, 2011 and Ser. No. 13/861,693 entitled “Linear Vacuum Robot with Z Motion and Articulated Arm” and filed on Sep. 5, 2013 the disclosures of which are all incorporated by reference herein in their entireties.

In aspects of the disclosed embodiment, the at least one substrate transport apparatus may have a general configuration known as SCARA (selective compliant articulated robot arm) type design, which includes an upper arm, a forearm and an end-effector, or from a telescoping arm or any other suitable arm design. In one aspect, the arm may have a band-driven configuration, a continuous loop configuration, or any other suitable configuration as will be described further below. Suitable examples of transfer arms can be found in, for example, U.S. patent application Ser. No. 12/117,415 entitled “Substrate Transport Apparatus with Multiple Movable Arms Utilizing a Mechanical Switch Mechanism” filed on May 8, 2008 and U.S. Pat. No. 7,648,327 issued on Jan. 19, 2010, the disclosures of which are incorporated by reference herein in their entireties. The operation of the transfer arms may be independent from each other (e.g. the extension/retraction of each arm is independent from other arms), may be operated through a lost motion switch or may be operably linked in any suitable way such that the arms share at least one common drive axis. The SCARA arm(s) may have one link, two links, or any suitable number of links and may have any suitable drive pulley arrangement such as a 2:1 shoulder pulley to elbow pulley arrangement and a 1:2 elbow pulley to wrist pulley arrangement. In still other aspects the substrate transport apparatus may have any other desired arrangement such as a frog-leg arm 216 (FIG. 2A) configuration, a leap frog arm 217 (FIG. 2D) configuration, a bi-symmetric arm 218 (FIG. 2C) configuration, or any other suitable configuration.

In another aspect, referring to FIG. 2E, the transfer arm 219 includes at least a first and second articulated arm 219A, 219B where each arm 219A, 219B includes an end effector 219E configured to hold at least two substrates S1, S2 side by side in a common transfer plane (each substrate holding location of the end effector 219E shares a common drive for picking and placing the substrates S1, S2) where the spacing DX between the substrates S1, S2 corresponds to a fixed spacing between side by side substrate holding locations. Suitable examples of substrate transport apparatus can be found in U.S. Pat. No. 6,231,297 issued May 15, 2001, U.S. Pat. No. 5,180,276 issued Jan. 19, 1993, U.S. Pat. No. 6,464,448 issued Oct. 15, 2002, U.S. Pat. No. 6,224,319 issued May 1, 2001, U.S. Pat. No. 5,447,409 issued Sep. 5, 1995, U.S. Pat. No. 7,578,649 issued Aug. 25, 2009, U.S. Pat. No. 5,794,487 issued Aug. 18, 1998, U.S. Pat. No. 7,946,800 issued May 24, 2011, U.S. Pat. No. 6,485,250 issued Nov. 26, 2002, U.S. Pat. No. 7,891,935 issued Feb. 22, 2011 and U.S. patent application Ser. No. 13/293,717 entitled “Dual Arm Robot” and filed on Nov. 10, 2011 and Ser. No. 13/270,844 entitled “Coaxial Drive Vacuum Robot” and filed on Oct. 11, 2011 the disclosures of which are all incorporated by reference herein in their entireties. The aspects of the disclosed embodiment are, in one aspect, incorporated into the substrate transport apparatus of a linear transport shuttle such as those described in, for example, U.S. Pat. Nos. 8,293,066 and 7,988,398 the disclosures of which are incorporated herein by reference in their entireties.

In the aspect of the disclosed embodiment shown in FIG. 1D, the arms of the substrate transport apparatus 26B, 26i may be arranged to provide what may be referred to as fast swap arrangement allowing the transport to quickly swap substrates (e.g. pick a substrate from a substrate holding location and then immediately place a substrate to the same substrate holding location) from a pick/place location. The substrate transport apparatus 26B, 26i may have any suitable drive section (e.g. coaxially arranged drive shafts, side by side drive shafts, horizontally adjacent motors, vertically stacked motors), for providing each arm with kinematic motion in any suitable number (N) of degrees of freedom (DOF) (e.g. manifested as independent axis of motion (such as Rᵢ, Φᵢ) of the arm links (e.g., upper/forearm) and independent axis of motion of each end effector of the arm 110, and defined by each independent axis of rotation of each arm link (upper, forearm, end effector) about its corresponding support joint). As seen in FIG. 1D, in this aspect the chambers/substrate stations 56A, 56, 30i (substantially similar to those described herein) may be located interstitially between transfer chamber modules 18B, 18i and may define suitable processing modules, load lock(s) LL, buffer station(s), metrology station(s) or any other desired station(s) as noted herein. For example the interstitial modules, such as chambers 56A, 56 and substrate station 30i, may each have stationary substrate supports/shelves 56S1, 56S2, 30S1, 30S2 that may cooperate with the substrate transport apparatus to effect transport or substrates through the length of the linear transport chamber 416 along longitudinal axis LXB of the linear transport chamber 416.

By way of example, substrate(s) may be loaded into the linear transport chamber 416 by tool interface section 12. The substrate(s) may be positioned on the support(s) of chamber 56A with the transport arm 15 of the interface section. The substrate(s), in chamber 56A, may be moved between chamber 56A and chamber 56 by the substrate transport apparatus 26B in module 18B, and in a similar and consecutive manner between chamber 56 and substrate station 30i (which may be a load lock) with substrate transport apparatus 26i (in module 18i) and between substrate station 30i and substrate entry/exit station 412 with substrate transport apparatus 26i in module 18i. This process may be reversed in whole or in part to move the substrate(s) in the opposite direction. Thus, in one aspect, substrates may be moved in any direction along longitudinal axis LXB and to any position along the linear transport chamber 416 and may be loaded to and unloaded from any desired module (processing or otherwise) communicating with the linear transport chamber 416. In other aspects, interstitial transport chamber modules with static substrate supports or shelves may not be provided between transport chamber modules 18B, 18i. In such aspects, transport arms of adjoining transport chamber modules may pass off substrates directly from end effector or one transport arm to end effector of another transport arm to move the substrate through the linear transport chamber 416.

The processing station modules may operate on the substrates through various deposition, etching, or other types of processes to form electrical circuitry or other desired structure on the substrates. The processing station modules are connected to the transport chamber modules to allow substrates to be passed from the linear transport chamber 416 to the processing stations and vice versa. A suitable example of a processing tool with similar general features to the processing apparatus depicted in FIG. 1D is described in U.S. Pat. No. 8,398,355, previously incorporated by reference in its entirety.

FIG. 1E is a schematic illustration of a substrate processing apparatus 11090A which may be substantially similar to the semiconductor tool stations described above. Here, the substrate processing apparatus 11090A includes separate/distinct in-line processing sections 110305A, 110305B, 11030SC connected to a common atmospheric front end 11000. Each of the processing sections 11030SA, 11030SB, 11030SC includes a process module 11030 (e.g., forming a vacuum back end 11020) and a load lock 11010 (substantially similar to those described herein). In this aspect, at least one of the in-line processing sections 11030SA, 11030SB, 11030SC is configured to process a substrate S1, S2, S3 that has a different predetermined characteristic than the substrates processed in the other in-line processing sections 110305A, 110305B, 11030SC. For example, the predetermined characteristic may be a size of the substrate. In one aspect, for exemplary purposes only, in-line processing section 11030SA may be configured to process 200 mm diameter substrates, in-line processing section 11030SB may be configured to process 150 mm substrates, and in-line processing section 11030SC may be configured to process 300 mm substrates. In one aspect, at least one of the substrate transport apparatus 11013, 11014 is configured to transport the different sized substrates S1, S2, S3 with a common end effector. In one aspect, each of the load port modules 11050 may be configured to hold and interface with, on a common load port module, cassettes 11050 which hold different size substrates S1, S2, S3. In other aspects, each load port module 11050 may be configured to hold a predetermined cassette corresponding to a predetermined sized substrate. Processing substrates of different sizes with at least one common substrate transport apparatus 11013, 11014 may increase throughput and decrease machine down time with respect to single substrate batch processing.

FIG. 1F is a schematic illustration of a substrate processing apparatus 11090B substantially similar to substrate processing apparatus 11090. However, in this aspect, the process modules 11030 and load port modules 11005 are configured to process substrates having different sizes as described above with respect to substrate processing apparatus 11090A. In this aspect, the process modules 11030 may be configured to process substrates having different sizes or in other aspects, process modules may be provided that correspond to the different size substrates being processed in the substrate processing apparatus 11090B.

Referring to FIGS. 3A and 3B, an exemplary chamber such as load lock 300 is illustrated in accordance with aspects of the present disclosure. The vacuum load lock 300 (referred to herein as a “load lock” for convenience) may be similar to those described above with respect to FIGS. 1A-1F and provide for the introduction of temporal structures and/or features such as non-production materials into the semiconductor substrate processing system(s) such as those described above with respect to FIGS. 1A-1F substantially without breaking a vacuum atmosphere of the vacuum back end 301 of the semiconductor substrate processing system. The load lock 300 may be located between a vacuum back end 301 and a front end module (or min-environment/atmospheric front end) 302; while in other aspects, the load lock 300 may be located at any suitable location of the substrate processing systems described herein. The load lock 300 includes one or more substrate holding chambers 305. In the aspect illustrated in FIGS. 3A and 3B the load lock 300 includes two substrate holding chambers 305A, 305B; however, in other aspects there may be more or less than two substrate holding chambers 305. Each of the substrate holding chambers 305 include atmospheric and vacuum slot valves 307 that are configured to seal sealable apertures 397 the respective substrate holding chamber 305A, 305B such as when transferring substrates between the vacuum back end 301 and the front end module 602 through the load lock 300. Suitable examples of the slot valves can be found in, for example, U.S. Pat. No. 8,272,825 issued on Sep. 25, 2012 (entitled “Load Lock Fast Pump Vent”) the disclosure of which is incorporated herein by reference in its entirety. Each slot valve 307 of the substrate holding chamber(s) 305 may be independently closable by suitable doors of the respective slot valve 307. The slot valves 307 may provide the environmental isolation employed to evacuate the load lock 300 after loading a substrate from the (atmospheric) front end 302 and to maintain the vacuum in (vacuum) back end 301, e.g., such as where the substrate is transferred to a transport chamber (such as in FIGS. 1A-1D and 1F) from the load lock 300, or where the substrate is transferred substantially directly to a processing module (such as in FIG. 1E) from the load lock 300.

Still referring to FIGS. 3A, 3B, and 4, as described above, an interior of the load lock 300 may define one or more independently isolatable and/or cycleable substrate holding chambers 305. Where there are two or more substrate holding chambers 305A, 305B, the substrate holding chambers 305A, 305B are disposed in a stacked arrangement (e.g., one above the other). In other aspects, the substrate holding chambers 305 may be disposed side by side or in any other suitable spatial relationship relative to each other. Both substrate holding chambers 305A, 305B may be compact chambers that allow for rapid cycling of the chamber atmosphere. Suitable examples of compact chambers can be found in U.S. Pat. No. 8,272,825 previously incorporated by reference herein, and U.S. Pat. No. 7,374,386 issued on May 20, 2008 (entitled “Fast Swap Dual Substrate Transport For Load Lock”) and U.S. Pat. No. 6,918,731 issued on Jul. 19, 2005 (entitled “Fast Swap Dual Substrate Transport For Load Lock”), the disclosures of which are incorporated by reference herein in their entireties. The substrate holding chambers 305A, 305B may each have independently closable transport openings 311, 312 (see FIGS. 3A and 3B), such as by suitable slot valves 307 (for example atmospheric and vacuum slot valves), in respective sides of the load lock 300. Accordingly, the transport direction of substrates through each substrate holding chamber 305A, 305B are along substantially parallel axes or transport planes X1, X2 (see FIG. 3C). In one aspect, the substrate holding chambers 305A, 305B may be configured so that the transport direction of substrates through each of the substrate holding chambers 305A, 305B is bi-directional. In other aspects, the substrate holding chambers may be configured so that a transport direction of substrates through one of the substrate holding chambers 305A, 305B is different than a transport direction of substrates through the other one of the substrate holding chambers 305A, 305B. As a non-limiting example, substrate holding chamber 305A may allow for the transfer of substrates from a front end unit to a processing chamber of a back end of a substrate processing system/tool while substrate holding chamber 305B allows for the transfer of substrates from the processing chamber to the front end unit. In other aspects, the substrate holding chambers may have corresponding transport openings on different sides of the modules as described above with respect to FIG. 1C. Each of the substrate holding chambers 305A, 305B and their respective slot valves 307 may be independently operable so that, for example, as substrates are cooled in one substrate holding chamber 305A, 305B, substrates can be placed in or removed from the other substrate holding chamber 305A, 305B.

In the aspects of the present disclosure, the slot valves 307, which for example, may be configured as removably connectable (e.g. bolt on or other suitable releasable connection) modules, may be located exterior to the substrate holding chambers 305 defined by the load lock 300. In other aspects, the slot valves 307 may be removably integrated within a wall of the load lock 300. Examples of suitable slot valves/load lock doors can be found in U.S. Pat. No. 8,272,825, the disclosure of which was previously incorporated by reference herein in its entirety. In other aspects the valves or a portion of the valves may not be removable from the load lock 300.

Still referring to FIGS. 3A, 3B, and 4, the load lock 300 may comprise a general core or skeletal frame section 30, and top closure 32 (FIGS. 3A-5F, also referred to herein as a cover) and bottom closure 34 (FIGS. 3C and 6A-7, also referred to herein as a cover). The frame section 30 may be a one piece member (e.g. of unitary construction) made of any suitable material such as aluminum alloy. In other aspects, the frame section 30 may be an assembly, and may be made of any suitable materials or number of sections. In the aspects of the present disclosure, the frame section 30 may generally define the load lock 300 exterior surfaces as well as the bounds of the substrate holding chambers 305 defined therein. A web member W, as seen in FIGS. 3A-3C, may section the load lock 300 to form the chamber stack. In other aspects, the load lock 300 may have more than one web member W, such as where there are more than two substrate holding chambers 305. In other aspects the chamber stack may be formed in any suitable manner. For example, the load lock 300 may have a general opening into which a chamber sub-module may be fit where the chamber sub-module includes a chamber stack having any suitable number of chambers. As may be realized, the substrate holding chambers 305A, 305B may be respectively closed at the top and bottom by closures 32, 34 as will be described herein. Interfaces for the slot valves 307 may be mated to the frame section 30 in any suitable manner. Examples of suitable interfaces for the slot valves 307 can be found in U.S. Pat. No. 8,272,825 previously incorporated by reference.

As may be realized, the load lock 300 is a communication module serving for through transfer of substrates between tool sections linked by the load lock 300. In other aspects, the load lock 300 is a communication module serving as an entry or exit for an adjacent tool section (see e.g., FIG. 1A where the load lock 300 may be coupled to a facet of the transport chamber 11025 (e.g., the load lock 300 having at least a slot valve for coupling to and providing passage to and from the transport chamber 11025). Accordingly, the height of the load lock 300 may be related to a height of adjoining sections or modules of the substrate processing system/tool, and may be dependent on such factors as the z axis travel of substrate transport apparatus in the adjoining module (responsible for throughput via the load lock module and which in turn may be delimited by such factors as size or z-drive and/or structural consideration of the module). As may be realized, providing the load lock 300 with a larger height than the available z-travel of the transport apparatus, may result in an unstable load lock volume increasing pump down/vent times. Similarly, providing a module height smaller than the available z-travel fails to use the whole travel bandwidth available from the transport apparatus, and thus unduly restricted throughput of the load lock module. In the aspects of the present disclosure, the features of the substrate holding chamber(s) 305 of the load lock 300, result in a configuration with a height that enables a stack of substrate holding chambers 305A, 305B to be defined within the load lock 300. As noted before, and shown in FIGS. 3A-3C, in the aspects of the present disclosure two substrate holding chambers 305A, 305B are formed in stacked arrangement in the load lock 300, though in other aspects the substrate holding chamber stack in the unitary load lock 300 may include more (or less) substrate holding chambers, such as three or more. As may be realized, providing multiple independent substrate holding chambers 305A, 305B, within the compact space envelope of the common load lock 300, generates multiple independent and unconstrained transport paths through the common load lock 300, each having a small internal volume (e.g., compared to a load lock having a single substrate holding chamber serving a front end module and a back end of a substrate processing system/tool substantially identical to that served by load lock 300), with a commensurate increase in throughput of the load lock 300. In aspects of the present disclosure each substrate holding chamber 305A, 305B may be generally similar to each other. In one aspect the substrate holding chambers 305A, 305B may have opposite hand configurations along the mid-plane separating the substrate holding chambers. In other aspects, the substrate holding chambers may be different, such as to handle different sizes and or types of substrates. In the aspects of the present disclosure, each of the substrate holding chambers 305A, 305B may have a height sufficient to hold a number of stacked substrates as will be described herein; while in other aspects, the substrate holding chambers 305A, 305B may be capable of holding one or more stacked substrates as desired.

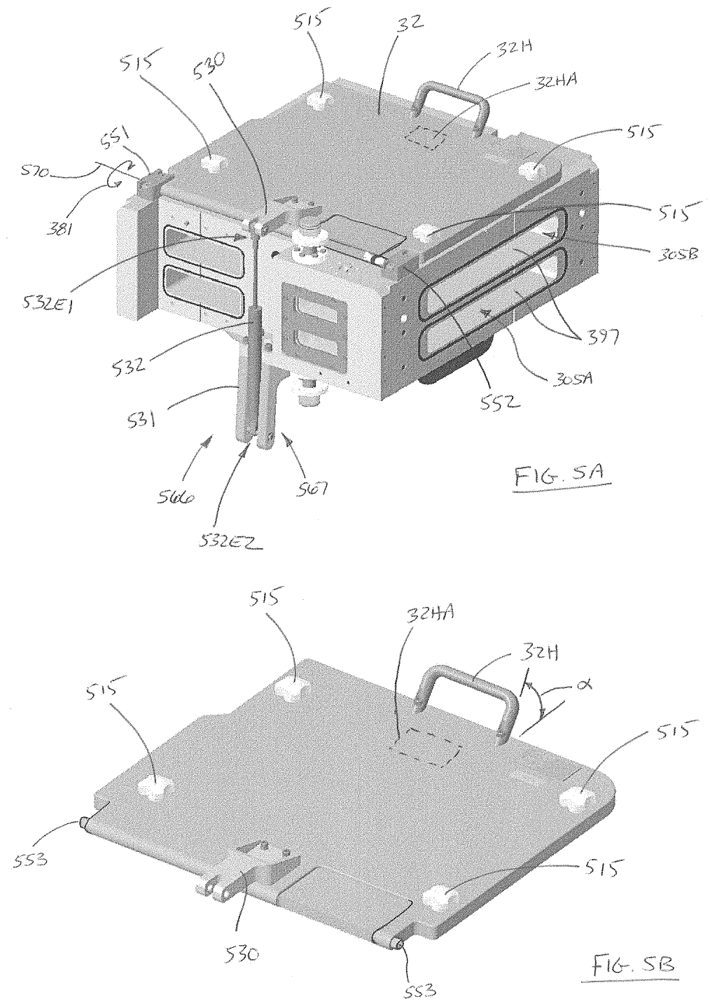

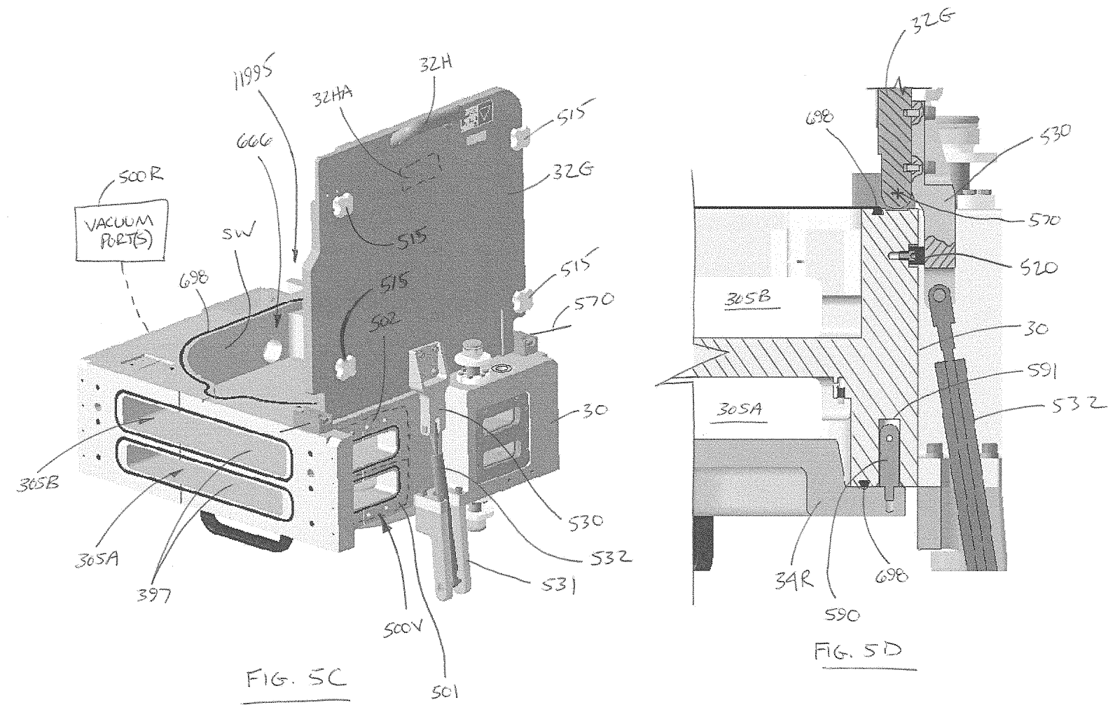

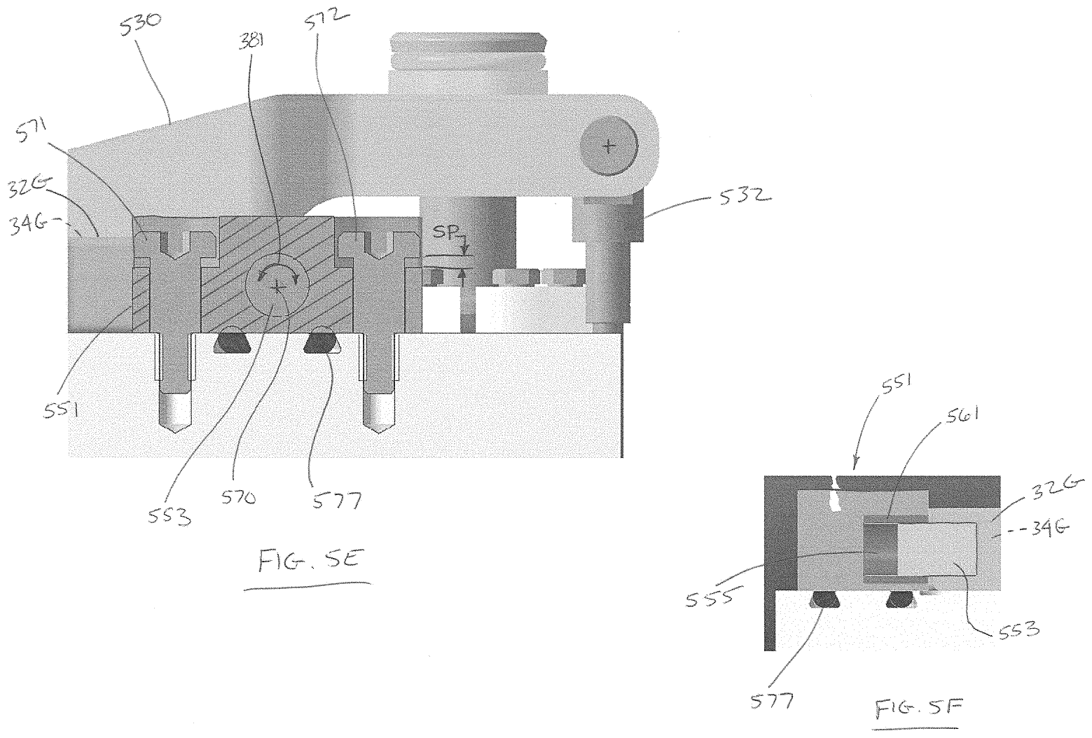

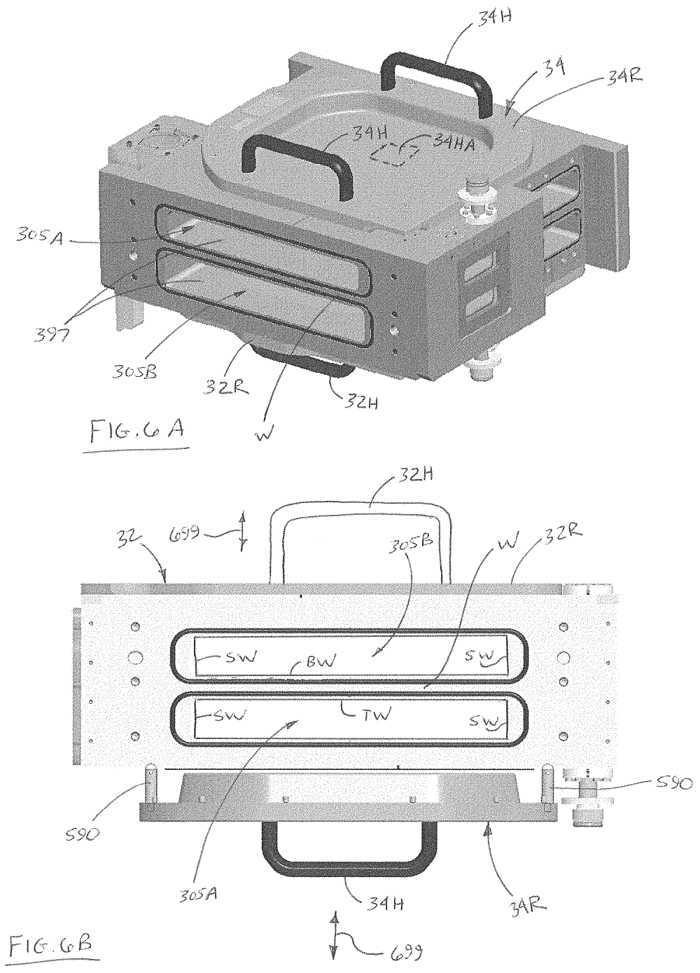

Referring to FIGS. 3A and 3B, in the aspects of the present disclosure, each substrate holding chamber 305A, 305B may have corresponding vacuum control valves 333A, 333B and vent valves 334A, 334B (such as with or without a diffuser) enabling independent cycling of the respective chamber atmospheres. The vacuum control valves 333A, 333B and the vent valves 334A, 334B may be arranged in modules that may be interchangeable with each other as described in, for example, U.S. Pat. No. 8,272,825, previously incorporated herein by reference. Any suitable gauges 335A, 335B may be coupled to a respective substrate holding chamber 305A, 305B for sensing a pressure of the atmosphere within the respective substrate holding chamber 305A, 305B. Referring also to FIG. 5C, the frame section 30 of the load lock 300 may have vacuum ports 500R and vent ports 500V formed therein for the respective substrate holding chambers 305A, 305B. The arrangement of the vacuum ports 500R and vent ports 500V shown in FIGS. 3A, 3B and 5C are exemplary, and in other aspects the vacuum and vent ports may have any other suitable arrangement. The vacuum ports 500R may be located on one side of the frame section 30 while the vent ports 500V may be located on another side of the frame section 30; while in other aspects, the vacuum ports and vent ports may be located on a common (i.e., the same) side of the frame section 30. As illustrated in, e.g., FIGS. 3A and 3B, the vacuum ports 500VA, 500VB may be vertically offset from one another; while in other aspect, the vacuum ports 500VA, 500VB may be vertically in-line with each other or have any other suitable spatial relationship with each other. Similarly, the vent ports 500RA, 500RB may be vertically offset from one another; while in other aspect, the vent ports 500RA, 500RB may be vertically in-line with each other or have any other suitable spatial relationship with each other.

The load lock 300, as shown in FIGS. 3A-3C, may have a modular arrangement, enabling the load lock to be built out in similar or different configurations by installing desired modules. For example, each of the vacuum ports 500VA, 500VA and each of the vent ports 500RA, 500RB may have any suitable mating interface (e.g., substantially similar to mating interface 501 that surrounds the respective port) to facilitate connection of a desired vacuum control valve 333A, 333B and/or a desired vent valve 334A, 334B to the port (and hence the frame section 30 of the load lock 300). In one aspect, two or more of the mating interfaces 501, 502 (mating interfaces for the vacuum ports 500R are substantially similar), for the respective ports may be configured to have a substantially similar mating arrangement (e.g. mapping flanges, sealing surfaces, bolting pattern) allowing any valve with a complementing mating interface to mate with the mating interface of either port. By way of example, as seen best in FIG. 3A, the vent valves 334A, 334B may be integrated into vent valve modules, each having a similar mating interface allowing either module to be interchangeably mounted to the vent port interface of either substrate holding chamber 305A, 305B in a manner similar to that described in U.S. Pat. No. 8,272,825, previously incorporated herein by reference in its entirety. Similarly, By way of example, as seen best in FIG. 3B, the vacuum control valves 333A, 333B may be integrated into vacuum valve modules, each having a similar mating interface allowing either module to be interchangeably mounted to the vacuum port interface of either substrate holding chamber 305A, 305B. It is noted that while the aspects of the present disclosure may be described with respect to separate vent and vacuum ports, in other exemplary embodiments, the valves may be configured to vent and pump out the chamber through a single port. For example, the valves may be configured with suitable valving characteristics to switch between a vacuum source and a venting source. In other alternate embodiments each module may have a vent and vacuum port so that the chamber(s) can be vented and/or pumped down with a single vent/vacuum module.

Referring to FIGS. 5C, 6B, 6C-6F, and 7, as noted above the load lock 300 may be configured to increase or maximize throughput of substrates that can be passed through the load lock 300 and the substrate processing tool, of which the load lock is coupled to. As described herein, the load lock 300 may communicate between different sections (such as those illustrated in FIGS. 1A-1F) of a substrate processing system/tool, each section having, for example, different atmospheres (e.g. inert gas on one side and vacuum on the other, or atmospheric clean air on one side and vacuum/inert gas on the other). In this example, the load lock 300 may define one or more substrate holding chambers 305, 305A, 305B therein for holding substrates. Each of the one or more substrate holding chamber 305, 305A, 305B may be capable of being isolated and capable of having chamber atmosphere cycles that match atmospheres in the tool sections adjoining the load lock 300. In the aspects of the present disclosure each of the substrate holding chamber(s) 305, 305A, 305B of the load lock 300 is compact allowing for rapid cycling of the substrate holding chamber 305, 305A, 305B atmosphere.

Still referring to FIGS. 5, 6B, 6C-6F, and 7, each of the substrate holding chambers 305, 305A, 305B of the load lock 300 is configured to have a minimized internal volume with respect to, for example, the paths of motion of the components within the respective substrate holding chamber 305, 305A, 305B and/or the path of substrate(s) passing though the respective substrate holding chamber 305, 305A, 305B. In one aspect, the side walls SW of the substrate holding chamber 305, 305A, 305B may be contoured to follow a path PTH of the substrate S while allowing only a minimal clearance MC (noting the minimal clearance may be inclusive of any transport carrier cassette 401—see FIG. 4—inserted within the respective substrate holding chamber 305, 305A, 305B) between the substrate S and the side walls SW. The path PTH in this aspect is illustrated as a substantially straight path for exemplary purposes, but in other aspects the path may be curved or have both straight and curved portions. In this example, the bottom wall BW and/or top wall TW of each substrate holding chamber 305, 305A, 305B may also be contoured to provide only a minimal clearance MC between the substrates S and/or portions of a substrate transport (e.g., such as an end effector) passing through the load lock 300 and the top wall TW and/or bottom wall BW of the substrate holding chamber 305, 305A, 305B. With respect to the top substrate holding chamber 305B the top wall TW and a contour thereof may be formed, at least in part, by the top closure 32. With respect to the bottom substrate holding chamber 305B, the bottom wall BW and a contour thereof may be formed, at least in part, by the bottom closure 34. Each of the compact chambers 305, 305A, 305B has a selectable configuration, selectable substantially freely (i.e., with minimal down time of the process apparatus/system) between different predetermined configurations of different temporal structures and features as will be further described.

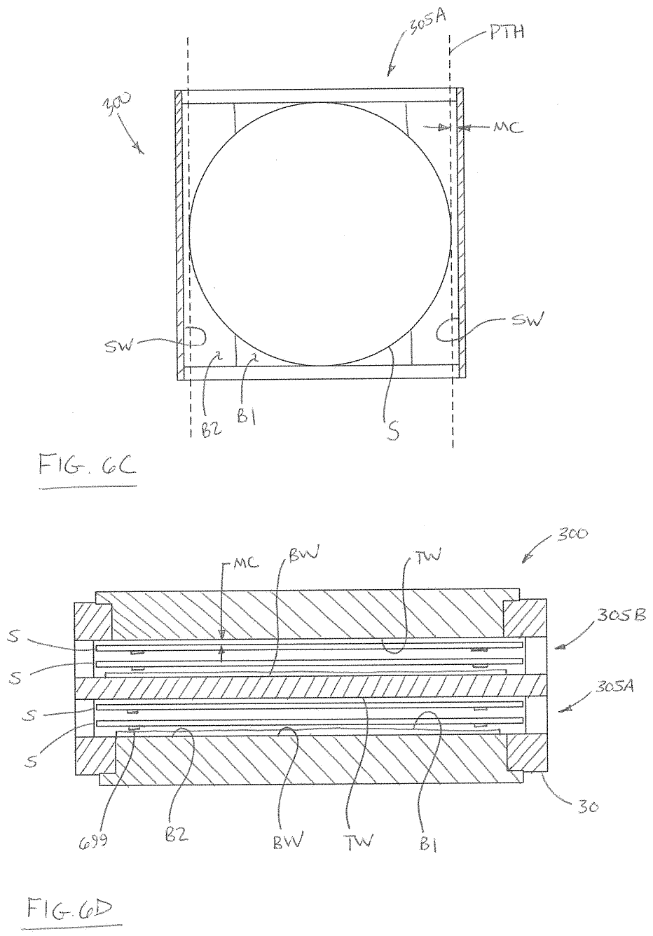

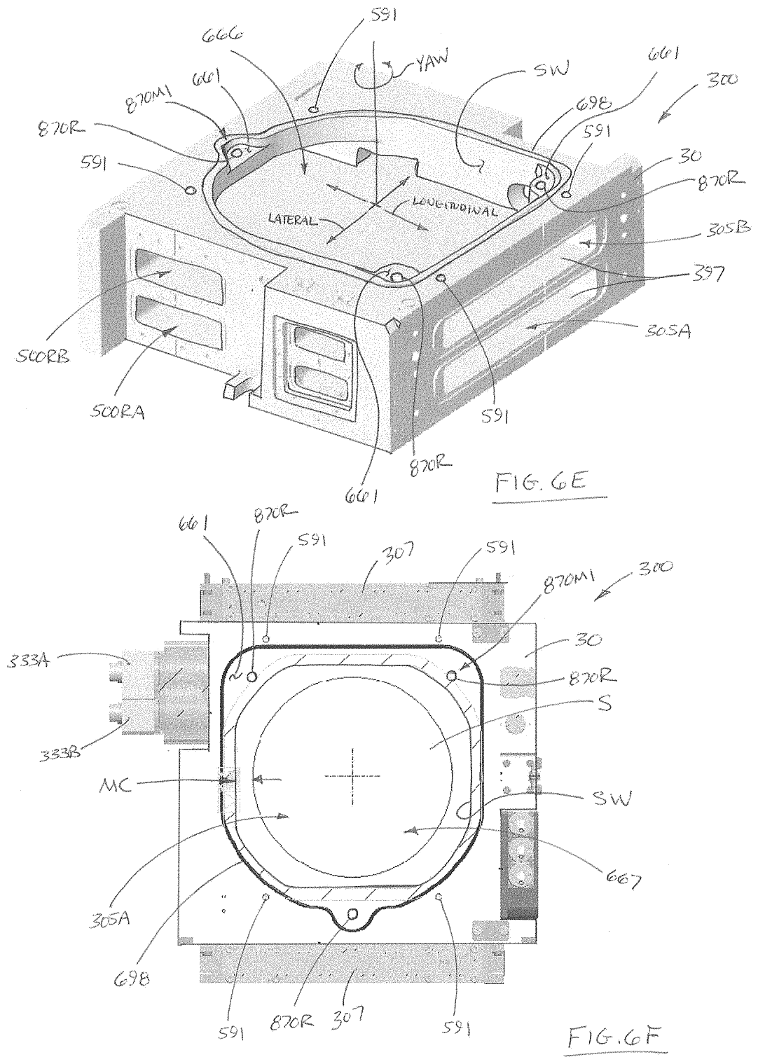

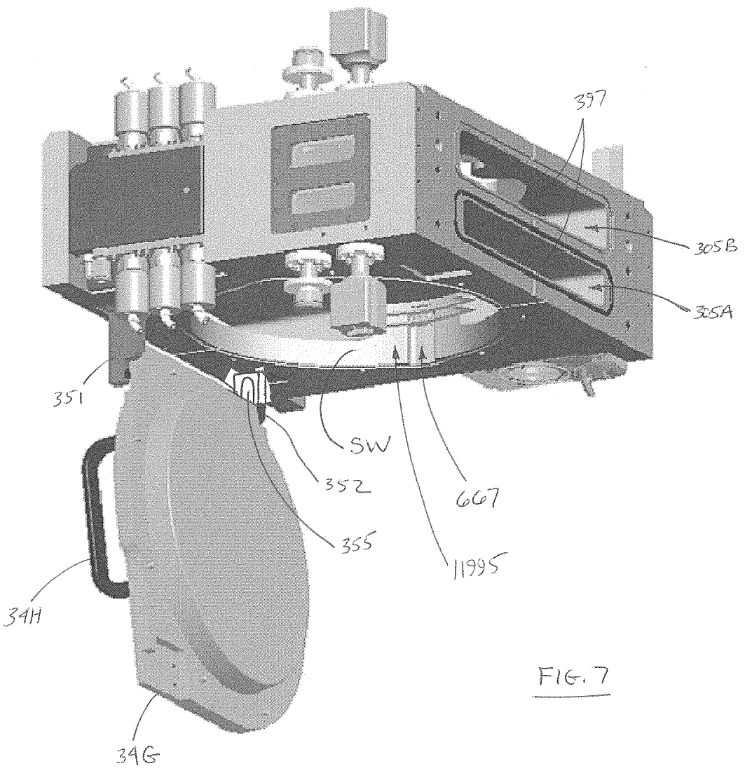

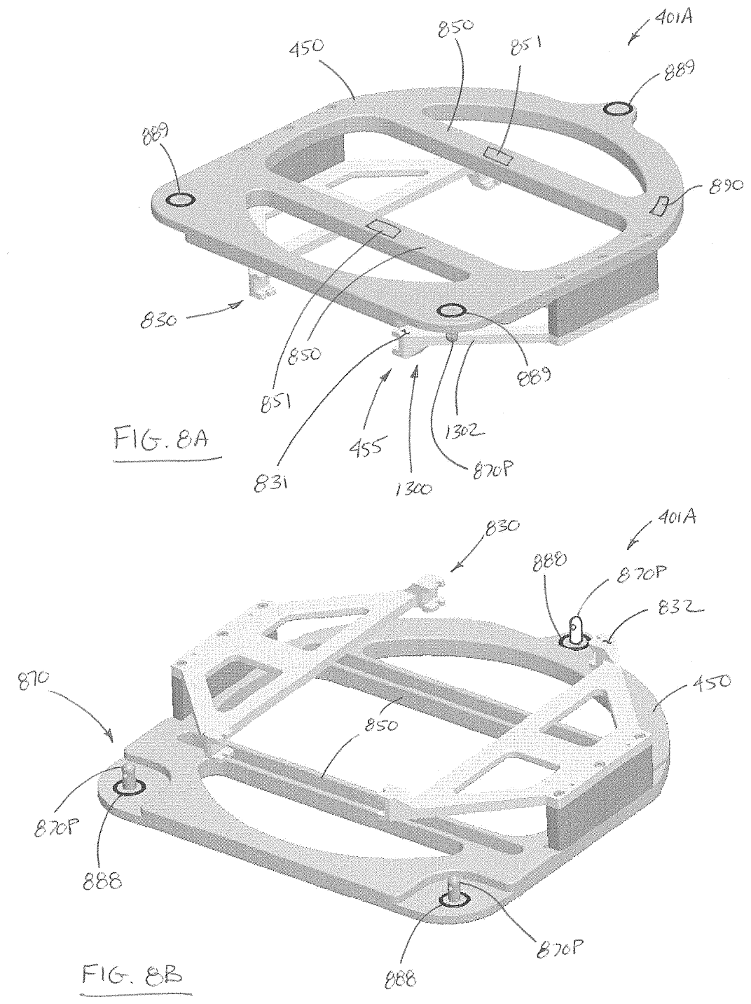

For example, referring to substrate holding chamber 305A (chamber 305B may be substantially similar) surface of section B1 of the bottom of the substrate holding chamber 305A may be raised relative to the surface of section B2 of the bottom of the substrate holding chamber 305A (see FIGS. 6C and 6D). For example, section B1 may only provide clearance for the substrate S seated on substrate supports 699 while section B2 provides clearance for, e.g., tines of an end effector of a transfer apparatus (such as those described above) to reach underneath the substrate S for picking and placing the substrate S from/to the substrate supports 699. As may be realized the top of the substrate holding chamber 305A (substrate holding chamber 305B may be substantially similar) may also be contoured in a manner similar to that described above with respect to the bottom of the substrate holding chamber 305A. Suitable examples of load lock chambers with contoured internal surfaces include U.S. Pat. No. 7,374,386 issued on May 20, 2008 (entitled “Fast Swap Dual Substrate Transport For Load Lock”) and U.S. Pat. No. 6,918,731 issued on Jul. 19, 2005 (entitled “Fast Swap Dal Substrate Transport For Load Lock”) the disclosures of which are incorporated by reference herein in their entireties. In alternate embodiments the substrate holding chamber(s) 305, 305A, 305B may have any suitable shape and contour for minimizing the internal volume. As may be realized this minimized internal volume of the substrate holding chamber(s) 305, 305A, 305B minimizes the volume of gas moved into or out of the respective substrate holding chamber(s) 305, 305A, 305B during the pump down and vent cycles. This reduced volume of gas may reduce the cycle times for transferring a substrate(s) through the load lock 300 as less gas has to be evacuated or introduced into the respective substrate holding chamber(s) 305, 305A, 305B.

Referring to FIGS. 3A, 3B, and 4, as described above, the aspects of the present disclosure provide for a reconfigurable substrate holding location that may be employed to introduce temporal structures, such as the non-production (or other) materials into a semiconductor substrate processing system (such as those described above) substantially without breaking a vacuum atmosphere of a vacuum back end of the semiconductor substrate processing system. It is noted that while the aspects of the present disclosure are described with respect to load lock 300; the aspects of the present disclosure may be equally applied to any suitable load lock disposed between at least two modules of the substrate processing system for transferring the substrates between the at least two modules, a load lock that is dedicated to the introduction and removal of non-production materials, and/or a vacuum or atmospheric transport chamber (all of which are included in the expression “substrate holding location” used herein), where one or more transport carrier cassettes 401A-401n (the suffix “n” signifying any suitable integer that defines an upper limit on the number of transport carrier cassettes) are introduced and removed from the substrate holding location in a manner substantially similar to that described herein through any suitable closable/sealable opening(s) 666, 667 (see FIGS. 4, 5C, 6E, 6F, and 7) of the load lock 300.

Referring to FIGS. 5D, 6A, 6B, 6E, and 6F, one or more of the openings 666, 667 may be sealed by a respective removable closure 32R, 34R that may be entirely removed from the frame section 30 of the load lock 300. The removable closure 32R, 34R may have any suitable shape and size so as to engage the frame section 30 of the load lock 300 around a periphery of a respective opening 666, 667 (e.g., the removable closure extends past a periphery of the respective opening 666, 667 so as to engage/couple with the frame section 30 of the load lock 300). Any suitable seal 698 may be disposed around a periphery of the respective opening 666, 667 so that the seal 698 is compressed between the frame section 30 and the removable closure 32R, 34R so as to seal the respective opening 666, 667. The removable closure 32R, 34R may have one or more handles 32H, 34H configured to allow a user and/or any suitable automated equipment to couple and decouple the respective removable closure 32R, 34R to/from the frame section 30. In one aspect the one or more handles 32H, 34H are configured to engage a human hand. Here the one or more handles 32H, 34H may extend from a respective removable closure 32R, 34R so as to have any suitable angle α (in a manner similar to that shown in FIG. 5B) relative to a major surface of the respective removable closure 32R, 34R. In other aspects, the one or more handles 32H, 34H comprise an automation interface 32HA, 34HA (see FIG. 6A) configured (e.g., with suitable kinematic/locating feature) to engage a robotic handler in a positionally repeatable manner.

In one aspect, the removable closure 32R, 34R includes locating pins 590 that are received by respective locating apertures 591 of the frame section 30 (see FIGS. 5D, 6B, 6E, and 6F); however, in other aspects, the locating pins may be located on the frame section 30 and the locating apertures 591 may be located on the removable closure 32R, 34R. The locating pins 590 and locating apertures 591 may provide guided movement between the removable closure 32R, 34R and the frame section 30 prior to removable closure 32R, 34R protrusion into the respective substrate holding chamber 305A, 305B. The removable closure 32R, 34R may be coupled to the frame section 30, for sealing/closing the respective opening 666, 667 in any suitable manner, such as by any suitable removable fasteners, clips, snaps, etc. In one aspect, the removable closure 32R, 34R may include thumb/knob screws 515 (substantially similar to those shown in FIGS. 5A-5C) that are held captive on the removable closure 32R, 34R, where the thumb/knob screws 515 are configured to couple the respective removable closure 32R, 34R to the frame section 30.

Referring to FIGS. 3A, 3B, 4, 5A-5F, 6E, 6F, and 7, one or more of the openings 666, 667 may be sealed by a respective hinged closure 32G, 34G. The hinged closure 32G, 34G may be substantially similar to the removable closure 32R, 34R but for being coupled to the frame section 30 by a hinge assembly. For example, the hinged closure 32G, 34G may have any suitable shape and size so as to engage the frame section 30 of the load lock 300 around a periphery of a respective opening 666, 667. Any suitable seal 698 (see FIGS. 4, 5C, and 5D) may be disposed around a periphery of the respective opening 666, 667 so that the seal 698 is compressed between the frame section 30 and the hinged closure 32G, 34G so as to seal the respective opening 666, 667. The hinged closure 32G, 34G may have one or more handles 32H configured to allow a user and/or any suitable automated equipment to pivot the hinged closure 32G, 34G about a hinge axis 570 to open and close (e.g., unseal and seal) the respective opening 666, 667 of the frame section 30. In one aspect the one or more handles 32H, 34H are configured to engage a human hand. Here the one or more handles 32H, 34H may extend from a respective hinged closure 32G, 34G so as to have any suitable angle α (see FIG. 5B) relative to a major surface of the respective hinged closure 32G, 34G. in other aspects, the one or more handles 32H, 34H comprise an automation interface 32HA, 34HA (see FIG. 3B) configured (e.g., with suitable kinematic/locating feature) to engage a robotic handler in a positionally repeatable manner.

Referring to FIGS. 3A, 3B, 4, and 5A-5F, each of the hinged closures 32G, 34G are pivotally coupled to the frame section 30 with respective hinge assembly 350. In one aspect, referring to FIGS. 3A and 3B, the hinge assembly 350 includes a first hinge member 351, a second hinge member 352, at least one hinge pin 353, and at least one stop 354. The first hinge member 351 and the second hinge member 352 are coupled to the frame section 30 of the load lock 300 in any suitable manner (e.g., by suitable chemical and/or mechanical fasteners, welding, etc.). In one aspect, the first hinge member 351 and the second hinge member 352 may be integrally formed with the frame section 30. In the aspect shown in the figures, the first hinge member 351 and the second hinge member 352 are spaced from each other so at least a portion of the respective hinged closure 32G, 34G is disposed between the first hinge member 351 and the second hinge member 352, where the at least one hinge pin 353 extends from the hinged closure 32G, 34G into an elongated slot 355 of a respective one of the first hinge member 351 and the second hinge member 352; however, in other aspects the first and second hinge members 351, 352 and the hinged closures 32G, 34G may have any suitable configuration that forms a hinged coupling between the first and second hinge members 351, 352 and the respective hinged closure 32G, 34G. At least one of the first hinge member 351 and the second hinge member 352 includes a recess 356 configured to receive a respective one of the at least one stop 354. Here the at least one stop 354 is configured as a pin that protrudes from a surface of the hinged closure 32G, 34G and the recess 356 is shaped to receive and retain the pin so as to hold the hinged closure 32G, 34G in an open position (see FIG. 4); however, in other aspects, the at least one stop 354 and recess 356 may have any suitable configurations for holding the hinged closure 32G, 34G in the open position. It is noted that the open position of the hinged closure 32G, 34G positions the hinged closure 32G, 34G relative to the frame section 30 of the load lock 300 so as to provide unhindered ingress and egress of the transport carrier cassette 401 into and out of a respective substrate holding chamber 305A, 305B. In one aspect, the hinge assembly 350 may provide about a 90° rotation (given manufacturing tolerance buildup of hinge components) of the hinged closure 32G, 34G about a respective hinge axis 570; while in other aspects the hinge assembly 350 may provide more or less than about 90° rotation of the hinged closure 32G, 34G about the respective hinge axis 570.

Referring to FIGS. 3A, 3B, and 4, in this aspect, to open the hinged closure 32G, 34G, a user grasps the handle 32H or automated equipment engages the automation interface 32HA and rotates the hinged closure 32G, 34G in a respective direction 381 about hinge axis 570. The hinged closure 32G, 34G may move in direction 382 so that the at least one stop 354 enters the recess 356 and is seated within the recess 356 to hold the hinged closure 35G, 34G in the open position shown in FIG. 4. To close the hinged closure 32G, 34G, the hinged closure 32G, 34G may move in direction 382 so that the at least one stop 354 exits the recess 356 so that the hinged closure 32G, 34G may be rotated in direction 381 about hinge axis 570 to a closed position (e.g., shown in FIGS. 3A and 2B). As may be realized, the hinge axis 570 may “float” (e.g., move) in direction 382 within the elongated slot 355 so that the at least one stop 354 enters and exits the recess 356. As may also be realized, the recess 356 may be configured (e.g., such as with an “L” shaped or any other suitable configuration) as shown in FIGS. 3D and 7 so as to retain or otherwise prevent swinging of the hinged closure 34G disposed on the bottom of the load lock 300. The recess 356 may be configured such that the at least one stop 354 is retained within the recess 356 at least in part by, e.g., the Earth's gravitational force (or any suitable biasing force) acting on the hinged closure 32G, 34G.

Referring to FIGS. 5A-5F, the hinge assembly 566 includes first hinge member 551, a second hinge member 552, at least one hinge pin 553, and a biasing assembly 567. The hinge assembly 566 will be described herein with respect to top closure 32; but it should be understood that bottom closure 34 may have a substantially similar hinge assembly 566 unless otherwise noted. In this aspect, the first hinge member 551 and second hinge member 552 are arranged relative to the respective hinged closure 32G, 34G in a manner similar to that described above, where at least one hinge pin 553 extends through the respective hinged closure 32G, 34G and into a recess 555 of a respective one of the first hinge member 551 and second hinge member 552. As may be realized, the hinged closure 32G, 34G pivots in direction 381 about hinge axis 570 formed by a mating interface between the at least one hinge pin 553 and the recess 555. In one aspect, any suitable bushing 561 may be provided within the recess 555 where the hinge pin 553 is inserted into the bushing 561. In one aspect, the bushing 561 may be constructed of any suitable material (e.g., such as polytetrafluoroethene) that provides a lubricious surface on/along which the hinge pin 553 rotates.

Each of the first hinge member 551 and the second hinge member 552 may be coupled to the frame section 30 of the load lock in any suitable manner, such as by any suitable mechanical or chemical fasteners. In one aspect, the first hinge member 551 and the second hinge member 552 may be integrally formed with the frame section 30. In one aspect, as illustrated in FIGS. 5E and 5F, each of the first hinge member 551 and the second hinge member 552 may be coupled to the frame section with shoulder bolts 571, 572 such that a spacing SP between a bolt-head bottom and a respective one of the first hinge member 551 and the second hinge member 552 is substantially equal to an amount of compression of any suitable resilient member 577 (e.g., such as an O-ring) disposed between the respective one of the first hinge member 551 and the second hinge member 552. The space SP and the resilient member 577 provide for compliant movement between the hinged closure 32G, 34G and the frame section 30, such as when/during pumping and venting (e.g., atmospheric cycling) of the load lock 300.

The biasing assembly 567 includes a closure bracket 530, a frame bracket 531, and a biasing member 532. The closure bracket 530 is coupled to a respective hinged closure 32G, 34G in any suitable manner (e.g., such as with any suitable mechanical and/or chemical fasteners, welding, etc.); while in other aspects the closure bracket 530 is integrally formed with the respective hinged closure 32G, 34G. The frame bracket 531 is coupled to the frame section 30 in any suitable manner (e.g., such as with any suitable mechanical and/or chemical fasteners, welding, etc.); while in other aspects the frame bracket 531 is integrally formed with the frame section 30. The biasing member 532 is pivotally coupled at a one end 532E1 to the closure bracket 530, and is pivotally coupled at the other end 532E2 to the frame bracket 531. The closure bracket 530, the frame bracket 531, and/or the biasing member 532 may be shaped and sized so as to provide about 90° rotation (as described above) of the hinged closure 32G, 34G about a respective hinge axis 570; while in other aspects the frame bracket 531, and/or the biasing member 532 may be shaped and sized so as to provide more or less than about 90° rotation of the hinged closure 32G, 34G about the respective hinge axis 570.

The biasing member 532 is illustrated in the figures as a linear biasing member; however, in other aspects any suitable torsional biasing member may be employed. Here, the biasing member 532 may be a gas spring or any other suitable linear biasing member such as a biased extension damper or a biased compression damper. In one aspect, with respect to the top closure 32, the biasing member 532 is configured so as to reduce an amount of operator applied opening force that is applied to the hinged closure 32G to open the hinged closure 32G. In other aspects, with respect to the top closure 32, the biasing member 532 is configured so as to open the hinged closure 32G substantially without operator applied force. In one aspect, the biasing member 532 may include an internal or external lock configured to hold the hinged closure 32G in the open position; while in other aspects, the first and second hinge members may include recesses and the hinged closure 32G may include at least one stop for holding the hinged closure 32G in the open position in lieu of or in addition forces applied by the biasing member 532. In one aspect, as illustrated in FIG. 5D, any suitable stop 520 may be provided on the frame section that contacts, e.g., the closure bracket 530 to define the open position or otherwise limit rotation of the hinged closure 32G relative to the frame section 30. The biasing member 532 may also provide for controlled/dampened movement of the hinged closure 32G for closing the hinged closure 32G.

In one aspect, with respect to the bottom closure 34, the biasing member 532 is configured so as to reduce an amount of operator applied closing force that is applied to the hinged closure 34G to close the hinged closure 34G. In other aspects, with respect to the bottom closure 34, the biasing member 532 is configured so as to close the hinged closure 34G substantially without operator applied force. In one aspect, the biasing member 532 may include an internal or external lock configured to hold the hinged closure 34G in the open position; while in other aspects, the first and second hinge members may include recesses and the hinged closure 34G may include at least one stop for holding the hinged closure 34G in the open position in lieu of or in addition forces applied by the biasing member 532. In one aspect, as illustrated in FIG. 5D, any suitable stop 520 may be provided on the frame section 30 that contacts, e.g., the closure bracket 530 to define the open position or otherwise limit rotation of the hinged closure 34G relative to the frame section 30. The biasing member 532 may also provide for controlled/dampened movement of the hinged closure 34G for opening the hinged closure 34G, where the controlled/dampened movement counteracts gravitational forces acting on the hinged closure 34G.

The hinged closure 32G, 34G may be coupled to the frame section 30, for sealing/closing the respective opening 666, 667, in any suitable manner, such as by any suitable removable fasteners, clips, snaps, etc. In one aspect, the hinged closure 32G, 34G may include thumb/knob screws 515 (see FIGS. 5A-5C) that are held captive on the hinged closure 32G, 34G, where the thumb/knob screws 515 are configured to couple the respective hinged closure 32G, 34G to the frame section 30 for sealing/closing the respective opening 666, 667.

Referring to FIGS. 4, 8A-8C, 9A, 9B, and 10A-10C, the transport carrier cassette(s) 401 will be described in greater detail. In one aspect, the transport carrier cassette(s) 401 are configured to interchangeably modify a shelf geometry of the load lock 300 for semiconductor substrate production, maintenance procedures, setup/calibration procedures, or any other suitable production/maintenance procedure of the semiconductor processing system/tool (examples of which include shelf configurations for holding non-production materials including, but are not limited to, special substrates, process chuck covers, end effectors, transport robot wrists, teaching/setup fixtures/equipment, inspection equipment, calibration wafers, measurement devices, transport chamber related components such as slot/gate valve doors, and process related components such as consumable rings, consumable ring support plates, chucks, and shelves). The modification of the shelf geometry may be a temporary modification effecting a maintenance or other non-production procedure. In one aspect, referring to FIG. 15, the load lock 300 may include fixed (e.g., stationary) shelves 15000 (which may be used for production of substrates) where the transport carrier cassette(s) 401 may be inserted within the load lock 300 (as described herein) to supplement the fixed supplement shelves 15000 (e.g., provide additional production substrate supports) or provide different supports (for holding items other than production substrates). In other aspects, as described herein, the load lock 300 could be devoid of fixed substrate supports 15000 and a transport carrier cassette 401 with substrate supports could be inserted into the load lock 300 for production of substrates. In still other embodiments, the load lock 300 may be configured with fixed supports/shelving 15000 to hold a non-production workpiece and a transport carrier cassette 401 may be inserted into the load lock 300 (e.g., in addition to the fixed support shelves already within the load lock 300) so as to provide supports/shelving for production substrates.

Each transport carrier cassette 401 includes an interchangeable cassette frame 450 constructed of any suitable materials, including but not limited to metals, plastics, and ceramics. In some aspects, any suitable coating(s) are applied to the interchangeable cassette frame 450 to, for example, protect transport carrier cassette(s) 401 from corrosive environments. In one aspect, the interchangeable cassette frame 450 is shaped and sized so as to substantially conform with an interior of the load lock 300 (see FIG. 4) and may interchangeably be inserted into either the top substrate holding chamber 305B or the bottom substrate holding chamber 305A, as will be described herein, so that interchangeable cassette frame 450 enters within the load lock 300 from the exterior through the intermediate entry 11995 opening 666, 667. As noted herein, the entry and removal of the interchangeable transport carrier cassette 401 through the intermediate entry 11995 opening 666, 667 loads and unloads the load lock 300 with the transport path interface 455 that interfaces, in the load lock 300, the interior transport path 11998 (see, e.g., FIGS. 1B, 1C, 1E, and 1F) coincident with the interchangeable transport carrier cassette 401 loaded in the load lock 300. As may be realized and will be described, one or more of the temporal structures or features (e.g., consumables, shelves, end effectors, teaching equipment/fixtures, etc.) loaded and unloaded via loading and unloading of the different transport carrier cassettes 401 defines the transport path interface 455 (i.e., one or more of said features directly or indirectly interface the transport path).

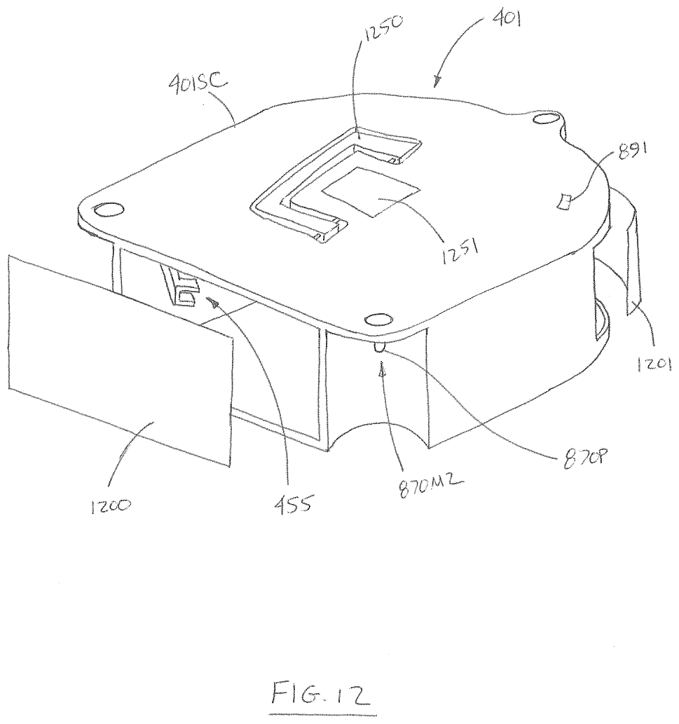

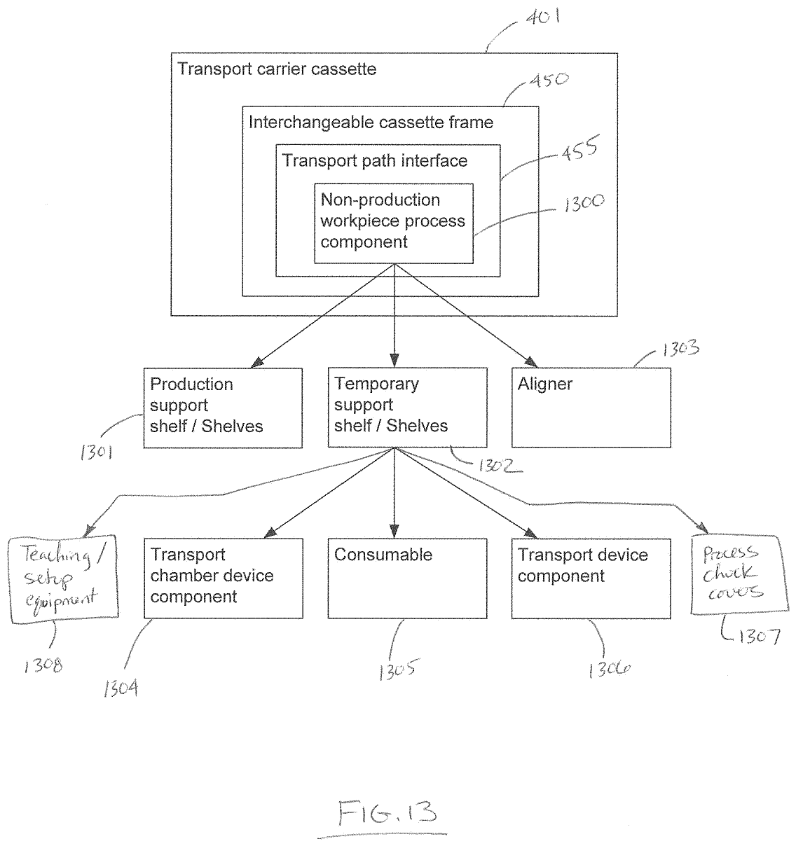

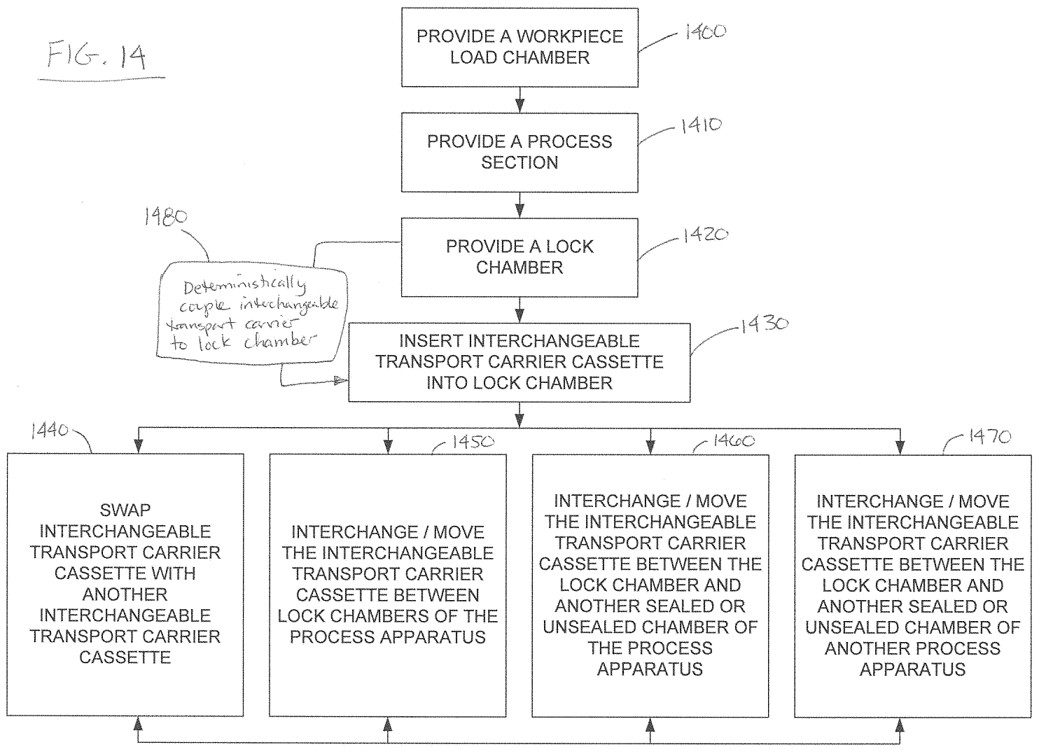

In one aspect, the transport carrier cassette 401 is configured for insertion into an operator carrier case or box 467 that is configured to enclose and stably hold (with any suitable configured cassette supports) the transport carrier cassette 401 for one or more of storage and transport of the transport carrier cassette 401. In another aspect, the transport carrier cassette 401 may be configured as a sealable carrier 401SC (see FIG. 12) that includes at least one removable door 1201, 1200 that is/are removed to open the sealable carrier 401SC for placement of the sealable carrier 401SC into the load lock 300 so that the interior transport path 11998 extends into (e.g., such as with a sealable carrier 401SC having one door) and/or through (e.g., such as with a sealable carrier 401SC having more than one door) the opened sealable carrier 401SC. The sealable carrier 401SC may be shaped and sized so as to substantially conform with an interior of the load lock 300 (e.g., in a manner substantially similar to that show in FIG. 4 with respect to transport carrier cassette 401) and may interchangeably be inserted into either the top substrate holding chamber 305B or the bottom substrate holding chamber 305A.

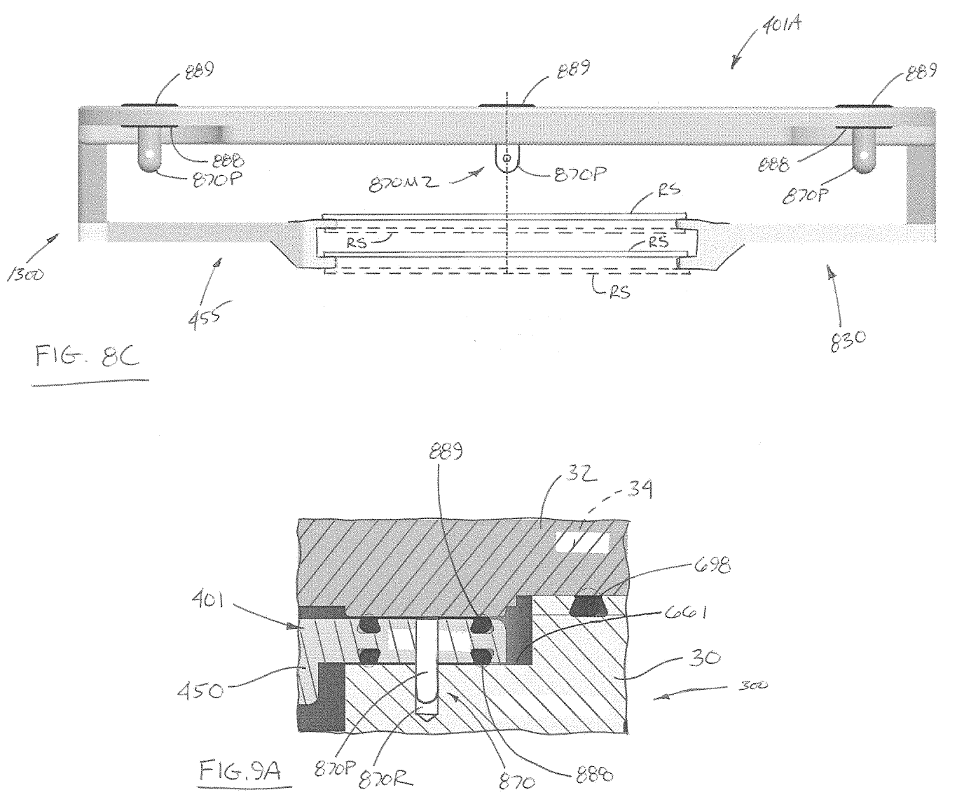

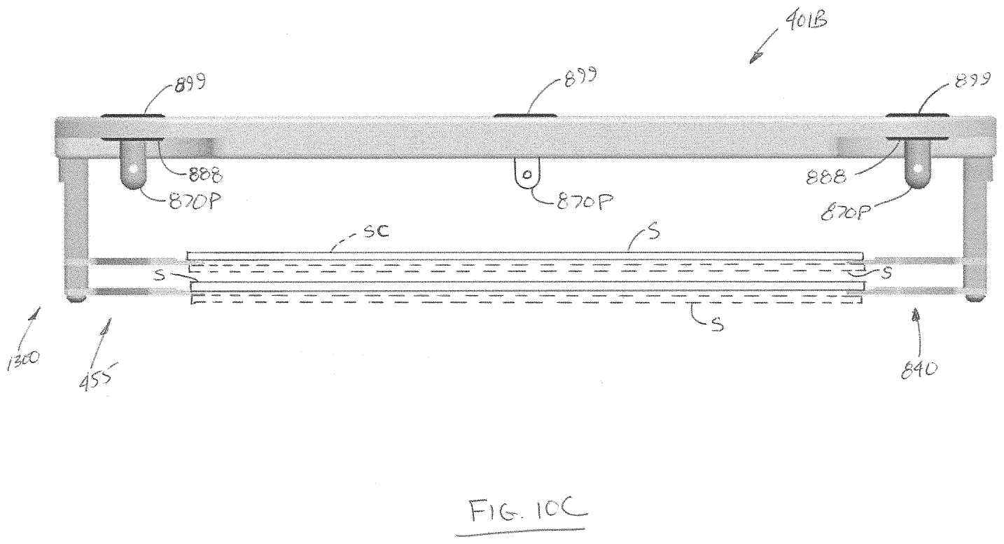

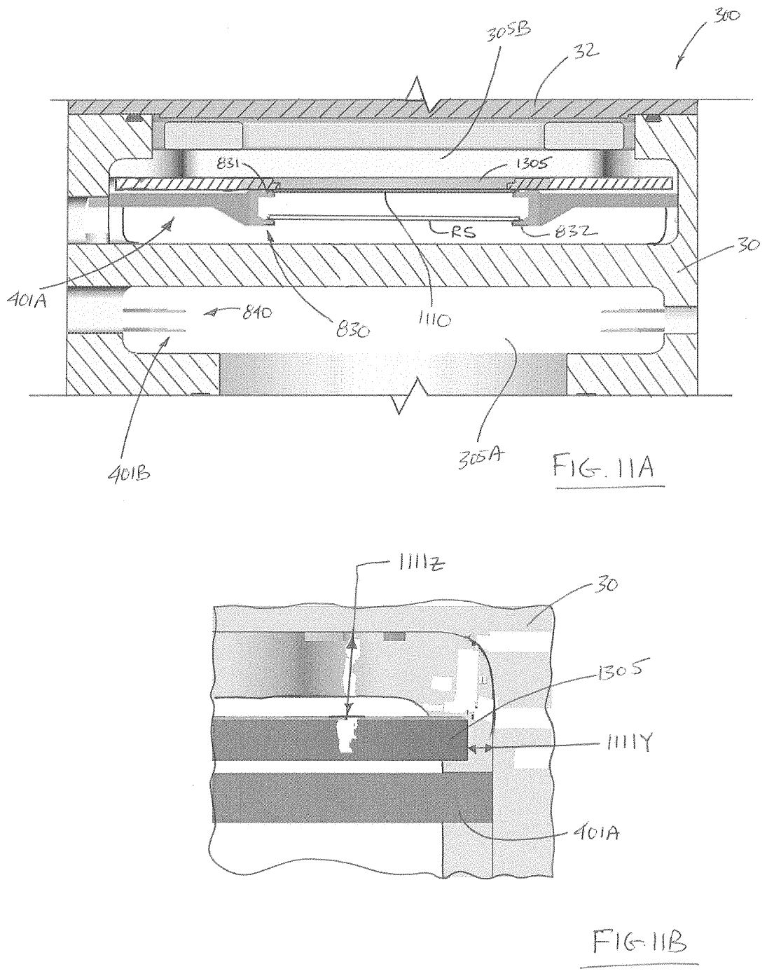

The transport carrier cassette 401, the operator carrier case 467, and the sealable carrier 401SC may have any suitable features that allow for operator and/or automated handling of the transport carrier cassette 401, the operator carrier case 467, and the sealable carrier 401SC. For example, referring to FIGS. 8A-8C and 10A-10C the interchangeable cassette frame 450 of the transport carrier cassette 401 may include one or more operator handles 850 that may be coupled to or integrated into the interchangeable cassette frame 450 in any suitable manner that facilitate transport of the transport carrier cassette 401 to and from the load lock 300. The interchangeable cassette frame 450 may also include, in lieu of or in addition to the operator handles 850, one or more automation interface 851 configured to provide automated gripping/engagement of the interchangeable cassette frame 450 by automated equipment (e.g., robot arm, overhead transport, etc.) in a positionally repeatable manner to facilitate transport of the transport carrier cassette 401 to and from the load lock 300. Similarly, referring to FIG. 12, the sealable carrier 401SC may include any suitable operator handle(s) 1250 and/or automation interface(s) 1251 configured to provide operator and/or automated transfer of the sealable carrier 401SC and the transport carrier cassette 401 therein to and from the load lock 300 or any suitable storage location. Referring to FIG. 4, operator carrier case 467 may include any suitable operator handle(s) 468 configured to provide operator transfer of the operator carrier case 467 and the transport carrier cassette 401 therein.

In one aspect, one or more of the transport carrier cassette 401 may include any suitable identification feature 890 that identifies a type of transport path interface 455 defined by the respective transport carrier cassette 401. In another aspect, one or more of the operator carrier case 467 and the sealable carrier 401SC may include any suitable identification feature 891 that identifies a type of transport path interface 455 defined by the respective transport carrier cassette 401 carried therein. The identification feature 890 may provide for identification of the transport carrier cassette 401, such as by an automated transport device (e.g., robot, overhead transport, etc.). In examples where the transport carrier cassette 401 is enclosed within the operator carrier case 467 and the sealable carrier 401SC the identification features 890, 891 may provide for identification of the transport carrier cassette 401 without opening the operator carrier case 467 and the sealable carrier 401SC. The identification features 890, 891 may be radio frequency identification tags, bar codes, text, or other suitable human/machine readable indicia or transmitter.

Referring to FIGS. 4, 8A-8, 10A-10C, and 13, the transport path interface 455 is coupled to the interchangeable cassette frame 450 in any suitable manner, such as by mechanical or chemical fasteners; while in other aspects, the transport path interface 455 may be integrally formed with the interchangeable cassette frame 450. Here the transport path interface 455 is coupled to the interchangeable cassette frame 450 and carried by the transport carrier cassette 401 so as to transport the transport path interface 455 to and from the process apparatus (such as those described herein) and repeatably position, on loading of the transport carrier cassette 401 into the load lock 300 through the intermediate entry 11995 opening 666, 667, the transport path interface 455 relative to the transport plane X1, X2 (see FIG. 3C) of the interior transport path 11998 (see, e.g., FIGS. 1B, 1C, 1E, and 1F) so as to interface the interior transport path 11998 with the transport path interface 455 at the repeatable position.

Referring to FIGS. 4 and 13, as noted before, the transport path interface 455 is a temporal structure or feature such as a non-production workpiece process component 1300. The non-production workpiece process component 1300 is a process component that is not a production workpiece and for convenience will be referred to herein as the non-production workpiece process component 1300. The process component that is not a production workpiece can process production workpieces or handle any other suitable items placed within or transferred through the load lock 300. In one aspect, the non-production workpiece process component 1300 is a production support such as, for example, shelf/shelves 1301 (an example of which is illustrated in FIGS. 10A-10C) configured to hold production substrate(s) S. In another aspect, the non-production workpiece process component 1300 is a temporary support such as, for example, shelf/shelves 1302 (an example of which is illustrated in FIGS. 8A-8C) configured to hold any suitable non-production items, setup/calibration equipment, and/or processing equipment. In still another aspect, the non-production workpiece process component 1300 is a substrate aligner 1303. As can be seen in FIG. 4, the different non-production workpiece process components 1300, 1301, 1303 may be incorporated into a respective transport carrier cassette 401, 401A-401n where for example, at least one of the transport carrier cassettes 401A may be configured to hold non-production materials. Another of the transport carrier cassettes 401B may be configured to hold production semiconductor substrates S. Another of the transport carrier cassettes 401C may be configured to hold calibration/setup substrates SC. Yet another of the substrate holding modules 401D may be configured with the substrate aligner 1303 for aligning substrates for processing. In other aspects, the transport carrier cassettes 401 may have any suitable configurations and/or any suitable processing equipment (e.g., aligners, optical character recognition, barcode readers, cameras, etc.) mounted thereon. In one aspect, there may be a transport carrier cassette 401 for holding a substrate having a first size and another transport carrier cassette 401 for holding a substrate having a different size, where the transport carrier cassettes 401 for holding different sized substrates can be employed in the load lock 300 for changing a size of the substrates (e.g., from 300 mm substrates to 250 mm substrates or any other suitable sizes) that can be cycled through the load lock.

In one aspect, the non-production workpiece process component 1300 is interchangeably coupled to the interchangeable cassette frame 450 with other non-production workpiece process components. Here the other non-production workpiece process components may be held or otherwise coupled to the non-production workpiece process component 1300. For example, the temporary support shelf/shelves 1302 may be configured to hold one or more other non-production workpiece process components that include, but are not limited to: transport chamber device components 1304 (e.g., slot valve doors, etc.), a transport device component 1306 (e.g., end effectors, wrist joints, etc. that are detached/re-attached from/to the substrate transport using passive or active decoupling/coupling mechanisms) that is configured to transport the production workpieces on the interior transport path, a non-production part(s) or workpiece(s) 1305 (e.g., consumable rings, ring supports, chucks, shelves, etc.) of a process in the vacuum back end 11020, process chuck covers 1307, and teaching/setup equipment 1308 (e.g., inspection equipment, calibration wafers, measurement devices, etc.).

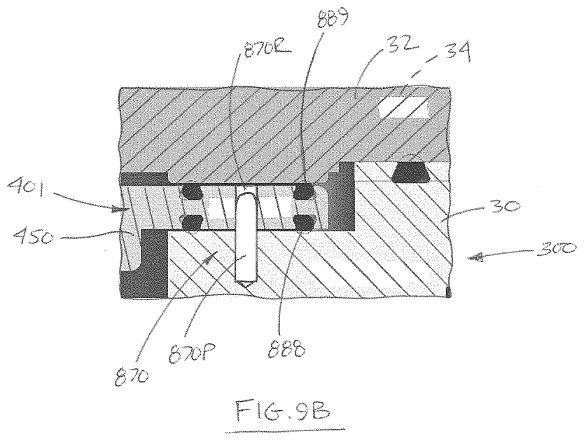

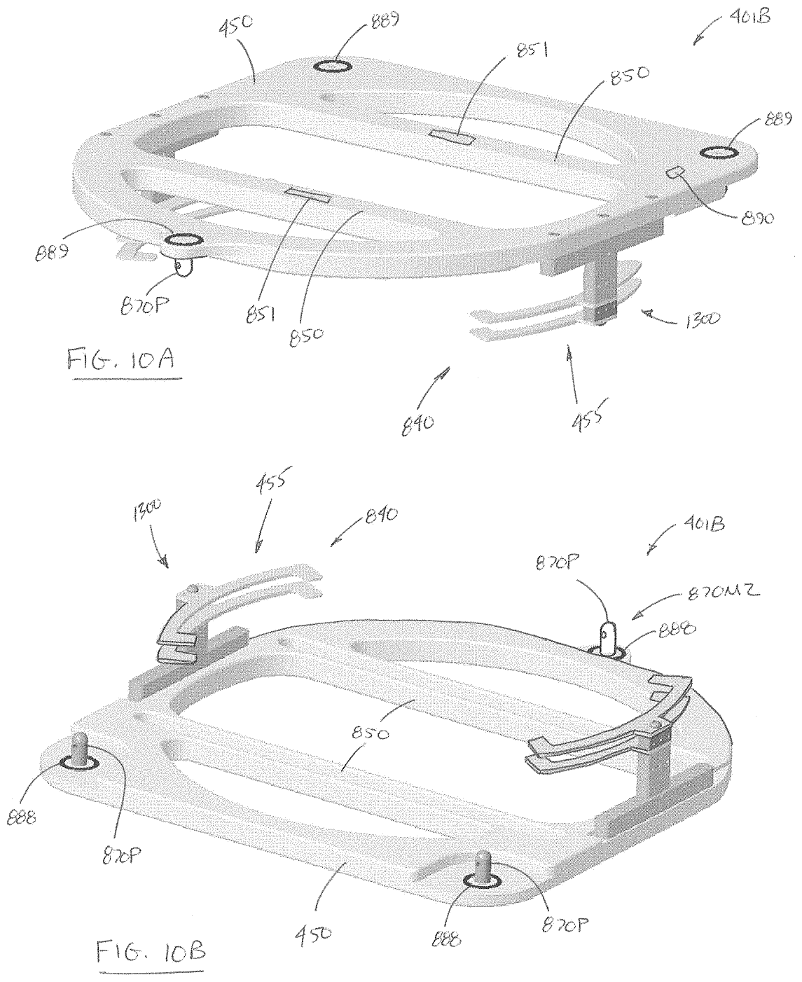

Referring to FIGS. 8A-8C, 9A, and 9B an exemplary transport carrier cassette 401, such as transport carrier cassette 401A will be described in greater detail. Here the transport path interface 455 comprises temporary support shelf/shelves 1302 which are coupled to the interchangeable cassette frame 450 as described above. The interchangeable cassette frame 450 (and hence the respective transport carrier cassette 401) includes a deterministic coupling 870 connected to the interchangeable cassette frame 450 that joins the interchangeable cassette frame 450 and the load lock 300 (FIG. 3) with the predetermined interchangeable transport carrier cassette 401, 401A loaded in the load lock 300 and effects, at least in part, the repeatable position of the transport path interface 455. The deterministic coupling 870 is a kinematic coupling that kinematically couples, substantially coincident with loading, the interchangeable transport carrier cassette 401, 401A in the load lock 300. Here the transport path interface 455 (and one of the different non-production workpiece process components corresponding thereto) is deterministically set in a predetermined repeatable position by the kinematic coupling relative to a locating feature (such as one or more of the substrate transport plane X1, X3 (see FIG. 3C) and a cassette seating surface 661 (see FIGS. 6E and 6F) of the load lock 300). Deterministically setting the transport path interface 455 in the predetermined repeatable position locates the sealable aperture 397 (e.g., sealed by the respective slot valves 307 (see FIGS. 3A-3C)) with respect to the interior transport path 11998.

The deterministic coupling 870 kinematically couples the interchangeable transport carrier cassette 401, 401A and the transport path interface 455 in at least two orthogonal constraint axis (e.g., at least in the lateral and yaw directions and in other aspects also in the longitudinal direction—see FIG. 6E) relative to the transport plane X1, X2 (see FIG. 3C). The deterministic coupling 870 is located in the load lock 300 with the interchangeable transport carrier cassette 401, 401A loaded in the load lock 300. The frame section 30 of the load lock includes a mating portion 870M1 (FIGS. 6E and 6F—e.g., pin(s) or recess(es)) of the deterministic coupling 870 and the interchangeable cassette frame 450 has another mating portion 870M2 (see FIGS. 8C, 10B, and 12—e.g., pin(s) or recess(es)) of the deterministic coupling 870 that deterministically couple the interchangeable transport carrier cassette 401, 401A and the respective different non-production workpiece process components carried by the transport carrier cassette 401, 401A substantially coincident with loading the transport carrier cassette 401, 401A in the load lock 300. For example, the deterministic coupling 870 includes at least one pin 870P dependent from the interchangeable cassette frame 450 (see FIGS. 8A-8C, 10A-10C, and 9A) or the load lock 300 (see FIG. 9B) and is configured so as to matingly engage within the load lock 300 a complementing receptacle 870R (see FIGS. 6E, 6F, and 9A) of the load lock 300 or the interchangeable cassette frame 450 (see FIG. 9B). Here, the at least one pin 870P includes more than one pin (in the example, shown there are three pins but in other aspects there may be two pins or more than three pins) in a deterministic pin arrangement on the interchangeable cassette frame 450 or the load lock 300 (such as on the frame section 30) that is positionally deterministic to the transport path interface 455 carried by the transport carrier cassette 401, 401A and effects the repeatable position of the transport path interface 455. The at least one pin 870P may be press/friction fit into the interchangeable cassette frame 450 or frame section 30 of the load lock 300, threaded into the interchangeable cassette frame 450 or frame section 30 of the load lock 300, or otherwise coupled to the interchangeable cassette frame 450 or frame section 30 of the load lock 300 in any suitable manner.

In one aspect, referring to FIGS. 8A, 8B, 9A, 9B, 10A, and 10B, the deterministic coupling 870 is disposed within the load lock 300 so as to be sealed from an interior of the load lock 300. In the example provided above, each of the at least one pin 870P mated to each of the complementing receptacle 870R is sealed from an interior of the load lock 300. Sealing the at least one pin 870P mated to each of the complementing receptacle 870R from the interior of the load lock 300 substantially prevents particulates that may be generated by the deterministic coupling from entering the interior of the load lock 300. Here, any suitable resilient members 888 may be disposed on the interchangeable cassette frame 450 (or in other aspects on the frame section 30 of the load lock 300) so as to circumscribe a respective one of the pins 870P. The resilient members 888 may be O-rings or any other member that effects a seal between two surfaces. Here the resilient members 888 are disposed on the interchangeable cassette frame 450 (or in other aspects on the frame section 30 of the load lock 300) so as to form a seal, between the interchangeable cassette frame 450 and the cassette seating surface 661 of the frame section 30 of the load lock 300, that circumscribes the interface between the pin 870P and the respective complementing receptacle 870R.

Other suitable resilient member 889 may be disposed on an opposite surface of the interchangeable cassette frame 450 from the resilient members 888, where the other resilient members 889 are disposed so as to be substantially in-line or otherwise substantially concentric with the pins 870P and the resilient members 888. The other resilient members 889 may be O-rings or other any other member that effects a seal between two surfaces. The other resilient members 889 may seal a through-hole, in the interchangeable cassette frame 450, in which the pin 870P is disposed. The other resilient members 889 are disposed on the interchangeable cassette frame 450 (or in other aspects on the closure 32, 34) so as to be compressed between the interchangeable cassette frame 450 and the closure 32, 34 with the closure 32, 34 in the closed position, where the compression of the other resilient members 889, at least in part, causes compression of the resilient members 888 and sealing of the deterministic coupling 870 within the load lock. In one aspect, as noted above with respect to FIG. 5E, the compliant movement of the hinged closure 32G, 34G, such as when/during pumping and venting (e.g., atmospheric cycling) of the load lock 300 may further compress the resilient members 888, 889.

Referring again to FIGS. 4, 8A-8C and 10A-10C, the interchangeable cassette frame 450 has supports 830, 840 (e.g., that form at least in part a portion of the transport path interface 455) connected thereto that in one or more aspects are arranged to engage and stably hold at least the one of the different non-production workpiece process components (e.g., such as the substrate aligner 1303, transport chamber device component 1304, non-production part 1305, and transport device component 1306) carried by the transport carrier cassette 401, 401A, 401B. Different interchangeable transport carrier cassettes 401A-401n have different supports connected to the interchangeable cassette frame 450, each of the different supports being arranged (e.g., shaped and sized) to engage and stably hold corresponding different non-production workpiece process components (e.g., such as the substrate aligner 1303, transport chamber device component 1304, non-production part 1305, and transport device component 1306) for transport with the transport carrier cassette 401A-401n, and in the load lock 300 with the transport carrier cassette 401A-401n loaded in the load lock 300.

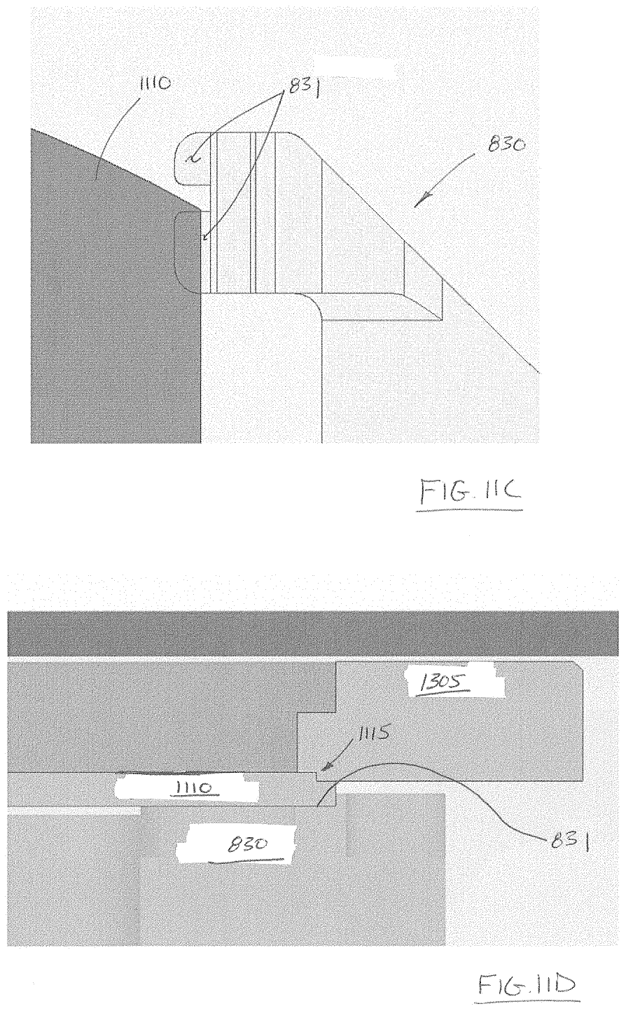

Referring to FIGS. 8A-8C and 11A-11D, the transport carrier cassette 401A is configured with a transport path interface 455 having supports 830 configured to support at least a non-production part 1305. Here, the supports have (first) support surfaces 831 configured to support the non-production part 1305 with the transport carrier cassette 401A in the top substrate holding chamber 305B and (second) support surfaces 832 configured to support the non-production part 1305 with the transport carrier cassette 401A in the bottom substrate holding chamber 305A. In this example, the non-production part 1305 is in the form of a ring where the non-production part is positioned upon a plate 1110 that forms an interface between the supports 830 and the non-production part 1305. The plate 1110 may be configured to provide any suitable clearance between the non-production part 1305 and the supports 830 while providing suitable lift clearance 11112 between the non-production part 1305 and the sealable apertures 397 (which may be sized for passage of the non-production part) and/or interior top surface of the substrate holding chambers 305A, 305B. Any suitable lateral/radial clearance 1111Y may also be provided with the valve size within the compact chamber. The plate 1110 may be shaped and sized so as to be stably held on the support surface(s) 831, 831 of the supports 830. In one aspect, the plate 1110 is configured to engage support surfaces of the supports 830 that are configured for holding production substrates; while in other aspects the plate 1110 is configured to engage any suitable portion of the supports 830 configured for stably holding the plate 1110. The plate 1110 may include any suitable retaining features 1115 (such as ledges, protrusions, or other surfaces) that engage mating surface(s) on the non-production part 1305 so that the non-production part 1305 is located and stably held on the plate 1110 in a predetermined location relative to the plate 1110.

Any suitable substrate transport of the process apparatus (such as those described above) may remove the plate 1110 and the non-production part 1305 thereon from the transport carrier cassette 401A. The substrate transport may install the non-production part 1305 in a process chamber or other suitable location in any suitable manner. In one aspect, the non-production part 1305 is detached from the plate 1110 upon installation of the non-production part 1305 and the substrate transport returns the plate 1110 to the transport carrier cassette 401A for removal of the plate 1110 from the process apparatus with the transport carrier cassette 401A.

In the aspect, shown in FIGS. 8A-8C, and 11A-11D, the supports 830 of the transport carrier cassette 401A may also be configured to stably hold substantially rectangular production substrates RS (FIGS. 8C and 11A) in a stacked arrangement regardless of whether the transport carrier cassette 401A is disposed within the top substrate holding chamber 305B or the bottom substrate holding chamber 305A. In FIG. 8C the substantially rectangular production substrates RS depicted by solid lines illustrate substrate holding positions with the transport carrier cassette 401A located within the top substrate holding chamber 305B and the substantially rectangular production substrates RS depicted by dashed lines illustrate substrate holding positions with the transport carrier cassette 401A located within the bottom substrate holding chamber 305A. Here the transport carrier cassette 401A is configured to hold two rectangular production substrates but in other aspects the transport carrier cassette 401A may be configured to hold less than two or more than two rectangular production substrates. As may be realized, one of the transport carrier cassettes 401A-4011n may be configured to hold two substantially rectangular production substrates while another of the transport carrier cassettes 401A-401n is configured to hold a different number of substantially rectangular production substrates.

Referring to FIGS. 10A-10C, the transport carrier cassette 401B is configured with a transport path interface 455 having supports 840 configured to support at least circular or disk shaped production substrates S. The transport carrier 401B may be otherwise substantially similar to that described above with respect to transport carrier cassette 401A. Here the substrates S depicted in solid lines in FIG. 10C are shown in substrate holding positions with the transport carrier cassette 401A located within the top substrate holding chamber 305B and the substrates S depicted by dashed lines illustrate substrate holding positions with the transport carrier cassette 401A located within the bottom substrate holding chamber 305A.

As may be realized, the supports of the non-production workpiece process component 1300 formed at least in part by the transport path interface 455 conform to a shape of an item held by the supports. As such, supports for supporting, e.g., a respective transport chamber device component 1304 or a respective transport device component 1306 are suitably shaped and sized for supporting such component. A transport carrier cassette, such as transport carrier cassette 401C (FIG. 4) configured for holding at least one transport device component 1306 may be configured to receive an end effector, that is detached from a substrate transport, on one support of the transport path interface 455 and provide another end effector, for coupling with the substrate transport, on another support of the transport path interface 455 so that the substrate transport may swap end effectors as desired. Similarly, a transport carrier cassette, such as transport carrier cassette 401E (FIG. 4) configured for holding at least one transport chamber device component 1304 may be configured to receive a transport chamber device, that transported by a substrate transport for replacement, on one support of the transport path interface 455 and provide a replacement transport chamber device, that is to be transported for installation by the substrate transport, on another support of the transport path interface 455 so that transport chamber devices may be replaced according to a preventative maintenance schedule or as necessary. In one or more aspects, the different shelves described herein may be employed on a common transport carrier cassette 401 so that different items are held on/by a common transport carrier cassette 401.

Referring again to FIGS. 4, 8A-8C, and 10A-10C the transport carrier cassettes 401, 401A-401n illustrated in the figures are configured for multi-directional substrate transport access. For example, the transport carrier cassettes 401, 401A-401n are configured so that a substrate or other item held by the transport carrier cassettes 401, 401A-401n can pass through (e.g., enter on one side and exit on another side) the load lock 300 (and the transport carrier cassettes 401, 401A-401n). In other aspects, the transport carrier cassettes 401, 401A-401n may be configured in any suitable manner such that access is provided to the substrate or other item held by the transport carrier cassettes 401, 401A-401n on but a single side of the load lock 300 (and the transport carrier cassettes 401, 401A-401n).

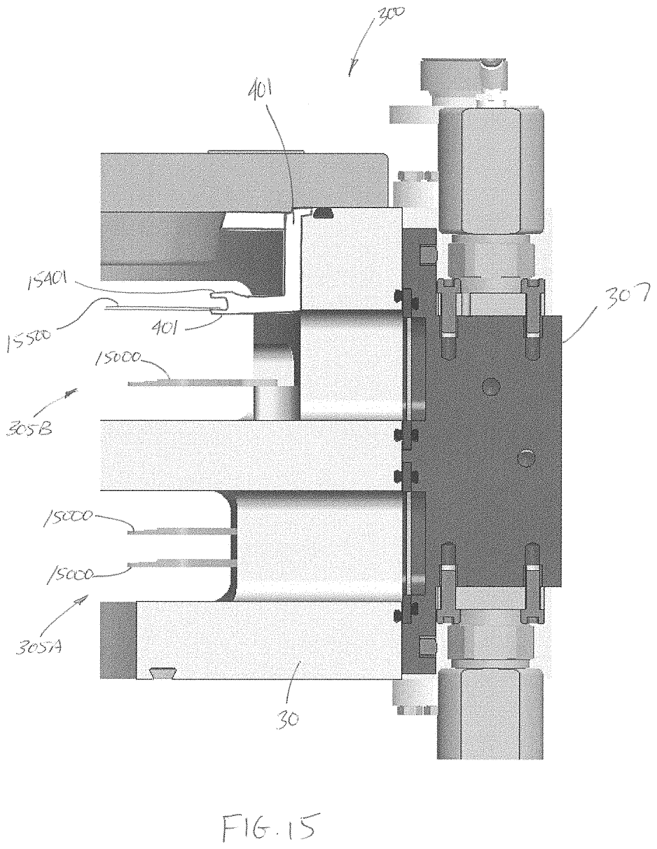

Referring to FIGS. 1A-1F, 4, 13, and 14 an exemplary method will be described in accordance with aspects of the present disclosure. In accordance with the method, a workpiece load chamber 11000 is provided (FIG. 14, Block 1400). A process section 11020 is also provided (FIG. 14, Block 1410). A lock chamber 11010 is provided (FIG. 14, Block 1420) and couples the load chamber 11000 to the process section 11020 as described herein. At least one interchangeable transport carrier cassette 401 is inserted into the lock chamber 11010 (FIG. 14, Block 1430) so as to effect a selectable configuration of the lock chamber 11010, the selectable configuration being selectable through the intermediate entry 11995 opening 666, 667 between different predetermined configurations each having a different temporal structure or features such as non-production workpiece process component 1300 within the lock chamber 11010. The selectable configuration being effected with loading of the at least one interchangeable transport carrier cassette 401, carrying one of the different non-production workpiece process components 1300, through the intermediate entry 11995 opening 666, 667 into the lock chamber 11010. The at least one interchangeable transport carrier cassette 401 is deterministically coupled to the lock chamber 11010 (FIG. 14, Block 1480) with a deterministic coupling as described herein.

The one of the different temporal structure or features, such as non-production workpiece process components 1300 may be swapped from the lock chamber 11010 by swapping the at least one interchangeable transport carrier cassette 401 in the lock chamber 11010 with another of the at least one interchangeable transport carrier cassette 401A-401N (FIG. 14, Block 1440) through the intermediate entry 11995 opening 666, 667. Swapping the at least one interchangeable transport carrier cassette 401 may enable replacement of a non-production workpiece such as, for example, a replaceable or consumable part (present in the process module or in another portion of the substrate processing system/apparatus) where, for example, the transport carrier cassette 401 with a new non-production workpiece therein is placed in the load lock to facilitate periodic maintenance. A substrate transport removes the new non-production workpiece from the transport carrier cassette 401 and swaps the new non-production workpiece with the used non-production workpiece in the process module 11030. The substrate transport returns the used non-production workpiece to the transport carrier cassette 401, where the transport carrier cassette 401 is replaced with another transport carrier cassette 401A-401N holding another new non-production workpiece that is to replace a used non-production workpiece in another process module 11030 in a manner similar to that just described. The replacement of the transport carrier cassette 401A-401N holding new non-production workpiece continues until all of the used non-production workpiece are replaced. A transport carrier cassette 401A-401N having production substrate supports may be placed in the load lock 11010 to continue production once the periodic maintenance is completed. In some aspects, referring also to FIG. 15, “dirty”/used workpieces/substrates may be placed on a bottom shelf 15000 (see chamber 305B) and “clean”/new workpieces/substrates may be placed on a top shelf 15401 (such as provided by the transport carrier cassette 401). In other aspect, the separate chambers 305A, 305B may be used for dirty and clean workpieces respectively. In one aspect, referring to chamber 305B in FIG. 15, a contamination barrier 15500 such as a plate or screen may be placed on the transport carrier cassette 401 between shelf 15401 and 15000 shelf. The contamination barrier 15500 may extend from wall to wall within the chamber 305B (e.g., edges of the barrier 15500 are immediately adjacent side walls of the chamber 305B) or the barrier 15500 may be sized so as to be larger than the workpieces held in the chamber 305B. The barrier 15500 could be spaced apart from and located between the support shelves 15401, 15000.

The at least one interchangeable transport carrier cassette 401 may be interchanged between each of the lock chamber 11010 of the process apparatus (FIG. 14, Block 1450). The at least one interchangeable transport carrier cassette 401 may be interchanged between the lock chamber 11010 of the process apparatus and another sealed or unsealed chamber (e.g., such as a process chamber, transfer chamber, front end module, etc.) of the process apparatus (FIG. 14, Block 1460). The at least one interchangeable transport carrier cassette 401 may be interchanged between the lock chamber 11010 of the process apparatus (such as one of the process apparatus in FIGS. 1A-1F) and another sealed or unsealed chamber of another process apparatus (such as another of the process apparatus in FIGS. 1A-1F) (FIG. 14, Block 1470).

In accordance with one or more aspects of the present disclosure a process apparatus comprises:

a front end with a load opening for loading, from an exterior of the process apparatus, production workpieces into the process apparatus;

a process section with a process environment arranged for processing the production workpieces, the process section being offset at a distance from and coupled to the front end via an interior transport path configured at least for transport of the production workpieces between the front end and the process section;

a load lock between the front end and the process section with the interior transport path extending through the load lock, the load lock having, in the distance offsetting the process section from the front end, an intermediate entry with an opening shunting the interior transport path to the exterior separate from the front end; and

a predetermined interchangeable transport carrier cassette, having an interchangeable cassette frame, configured so as to be entered within the load lock from the exterior through the intermediate entry opening, the entry and removal of the predetermined interchangeable transport carrier cassette through the intermediate entry opening loads and unloads the load lock with a transport path interface that interfaces, in the load lock, the interior transport path coincident with the predetermined interchangeable transport carrier cassette loaded in the load lock.

In accordance with one or more aspects of the present disclosure the transport path interface is a non-production workpiece process component coupled to the interchangeable cassette frame and carried by the predetermined interchangeable transport carrier cassette so as to transport the transport path interface to and from the process apparatus and repeatably position, on loading of the load lock through the intermediate entry opening, the transport path interface relative to a transport plane of the interior transport path so as to interface the interior transport path with the transport path interface at the repeatable position.

In accordance with one or more aspects of the present disclosure the non-production workpiece process component is interchangeably coupled to the interchangeable cassette frame with other non-production workpiece process components.

In accordance with one or more aspects of the present disclosure the non-production workpiece process component is swapped from the load lock by swapping the predetermined interchangeable transport carrier cassette in the load lock with another interchangeable transport carrier cassette through the intermediate entry opening.

In accordance with one or more aspects of the present disclosure the non-production workpiece process component is a replaceable or consumable part of a process in the process section.

In accordance with one or more aspects of the present disclosure the non-production workpiece process component is a temporary shelf of the load lock.

In accordance with one or more aspects of the present disclosure the non-production workpiece process component is a component of a transport device configured to transport the production workpieces on the interior transport path.

In accordance with one or more aspects of the present disclosure the process apparatus further comprises a deterministic coupling connected to the interchangeable cassette frame that joins the interchangeable cassette frame and the load lock with the predetermined interchangeable transport carrier cassette loaded in the load lock and effects, at least in part, the repeatable position of the transport path interface.

In accordance with one or more aspects of the present disclosure the deterministic coupling kinematically couples the predetermined interchangeable transport carrier cassette and transport path interface in at least two orthogonal constraint axis relative to the transport plane and is located in the load lock with the predetermined interchangeable transport carrier cassette loaded in the load lock.

In accordance with one or more aspects of the present disclosure the deterministic coupling is sealed from an interior of the load lock.

In accordance with one or more aspects of the present disclosure the deterministic coupling has at least one pin dependent from the interchangeable cassette frame or the load lock and is configured so as to matingly engage within the load lock a complementing receptacle of the load lock or the interchangeable cassette frame, and each of the at least one pin mated to each of the complementing receptacle is sealed from an interior of the load lock.

In accordance with one or more aspects of the present disclosure the at least one pin includes more than one pins in a deterministic pin arrangement on the interchangeable cassette frame or the load lock that is positionally deterministic to the transport path interface carried by the predetermined interchangeable transport carrier cassette and effects the repeatable position of the transport path interface.

In accordance with one or more aspects of the present disclosure the predetermined interchangeable transport carrier cassette is one or more of:

interchangeable between each of the load lock of the process apparatus,

interchangeable between the load lock of the process apparatus and another sealed or unsealed chamber of the process apparatus, and

interchangeable between the load lock of the process apparatus and another sealed or unsealed chamber of another process apparatus.

In accordance with one or more aspects of the present disclosure a process apparatus comprises:

a workpiece load chamber with a load opening for loading, from an exterior of the process apparatus, production workpieces into the process apparatus;

a process section with a process environment arranged for processing the production workpieces, the process section being offset at a distance from and coupled to the workpiece load chamber via an interior transport path configured at least for transport of the production workpieces between the load opening and process section; and

a lock chamber, between the load opening and process section, having a sealable aperture communicating with a sealed interior of the process section with the interior transport path extending through the sealable aperture of the lock chamber into the process section, the lock chamber having in the distance offsetting the process section from the workpiece load chamber, an intermediate entry with an opening shunting the interior transport path to the exterior separate from the workpiece load chamber;

wherein the lock chamber has a selectable configuration selectable through the intermediate entry opening between different predetermined configurations each having a different non-production workpiece process component within the lock chamber, the selectable configuration being effected with loading of at least one interchangeable transport carrier cassette, carrying one of the different non-production workpiece process components, through the intermediate entry opening into the lock chamber.

In accordance with one or more aspects of the present disclosure the lock chamber has a kinematic coupling that kinematically couples, substantially coincident with loading, the at least one interchangeable transport carrier cassette in the lock chamber, the one of the different non-production workpiece process components being deterministically set in a predetermined repeatable position by the kinematic coupling relative to a locating feature locating the sealable aperture with respect to the interior transport path.

In accordance with one or more aspects of the present disclosure the at least one interchangeable transport carrier cassette has an interchangeable cassette frame with a mating portion of the kinematic coupling deterministically coupling the interchangeable transport carrier cassette and the one of the different non-production workpiece process components carried by the interchangeable transport carrier cassette substantially coincident with loading the at least one interchangeable transport carrier cassette in the lock chamber.

In accordance with one or more aspects of the present disclosure the interchangeable cassette frame has supports connected thereto that are arranged to engage and stably hold the one of the different non-production workpiece process components carried by the interchangeable transport carrier cassette, and different interchangeable transport carrier cassettes have different supports connected to the interchangeable cassette frame, each of the different supports being arranged to engage and stably hold corresponding different non-production workpiece process components for transport with the interchangeable transport carrier cassette and in the lock chamber with the interchangeable transport carrier cassette loaded in the lock chamber.

In accordance with one or more aspects of the present disclosure the one of the different non-production workpiece process components is coupled to the interchangeable cassette frame and carried by the at least one interchangeable transport carrier cassette so as to transport the one of the different non-production workpiece process components to and from the process apparatus and repeatably position, on loading of the lock chamber through the intermediate entry opening, the one of the different non-production workpiece process components relative to a transport plane of the interior transport path so as to interface the interior transport path with the one of the different non-production workpiece process components at the repeatable position.

In accordance with one or more aspects of the present disclosure the one of the different non-production workpiece process components is interchangeably coupled to the interchangeable cassette frame with other non-production workpiece process components.

In accordance with one or more aspects of the present disclosure each of the different non-production workpiece process components is configured so as to be interchangeably carried by the interchangeable transport carrier cassette and deterministically positioned by the interchangeable transport carrier cassette loaded through the intermediate entry opening in the lock chamber.

In accordance with one or more aspects of the present disclosure the one of the different non-production workpiece process components is swapped from the lock chamber by swapping the at least one interchangeable transport carrier cassette in the lock chamber with another of the at least one interchangeable transport carrier cassette through the intermediate entry opening.

In accordance with one or more aspects of the present disclosure the one of the different non-production workpiece process components is a replaceable or consumable part of a process in the process section.

In accordance with one or more aspects of the present disclosure the one of the different non-production workpiece process components is a temporary shelf of the lock chamber.

In accordance with one or more aspects of the present disclosure the one of the different non-production workpiece process components is a component of a transport device configured to transport the production workpieces on the interior transport path.

In accordance with one or more aspects of the present disclosure the process apparatus further comprises a deterministic coupling connected to an interchangeable cassette frame of the at least one interchangeable transport carrier cassette, the deterministic coupling joins the interchangeable cassette frame and the lock chamber with the at least one interchangeable transport carrier cassette loaded in the lock chamber and effects, at least in part, a predetermined repeatable position of the one of the different non-production workpiece process components.

In accordance with one or more aspects of the present disclosure the deterministic coupling kinematically couples the at least one interchangeable transport carrier cassette and non-production workpiece process component in at least two orthogonal constraint axis relative to a transport plane of the interior transport path and is located in the lock chamber with the at least one interchangeable transport carrier cassette loaded in the lock chamber.

In accordance with one or more aspects of the present disclosure the deterministic coupling is sealed from an interior of the lock chamber.

In accordance with one or more aspects of the present disclosure the deterministic coupling has at least one pin dependent from the interchangeable cassette frame or the lock chamber and is configured so as to matingly engage within the lock chamber a complementing receptacle of the lock chamber or the interchangeable cassette frame, and each of the at least one pin mated to each of the complementing receptacle is sealed from an interior of the lock chamber.

In accordance with one or more aspects of the present disclosure the at least one pin includes more than one pins in a deterministic pin arrangement on the interchangeable cassette frame or the lock chamber that is positionally deterministic to the one of the different non-production workpiece process components carried by the at least one interchangeable transport carrier cassette and effects the predetermined repeatable position of the one of the different non-production workpiece process components.

In accordance with one or more aspects of the present disclosure the at least one interchangeable transport carrier cassette is one or more of:

interchangeable between each of the lock chamber of the process apparatus,

interchangeable between the lock chamber of the process apparatus and another sealed or unsealed chamber of the process apparatus, and

interchangeable between the lock chamber of the process apparatus and another sealed or unsealed chamber of another process apparatus.

In accordance with one or more aspects of the present disclosure, the lock chamber comprises one of a metrology chamber, a load lock chamber, an inspection station, an aligner station, a buffer station, and a transport chamber.

In accordance with one or more aspects of the present disclosure a method comprises:

providing a workpiece load chamber, the workpiece load chamber having a load opening for loading, from an exterior of a process apparatus, production workpieces into the process apparatus;

providing a process section, the process section having a process environment arranged for processing the production workpieces, the process section being offset at a distance from and coupled to the workpiece load chamber via an interior transport path configured at least for transport of the production workpieces between the load opening and process section;

providing a lock chamber, between the load opening and process section, the lock chamber having a sealable aperture communicating with a sealed interior of the process section with the interior transport path extending through the sealable aperture of the lock chamber into the process section, the lock chamber having in the distance offsetting the process section from the workpiece load chamber, an intermediate entry with an opening shunting the interior transport path to the exterior separate from the workpiece load chamber; and

inserting at least one interchangeable transport carrier cassette into the lock chamber so as to effect a selectable configuration of the lock chamber, the selectable configuration being selectable through the intermediate entry opening between different predetermined configurations each having a different non-production workpiece process component within the lock chamber, the selectable configuration being effected with loading of the at least one interchangeable transport carrier cassette, carrying one of the different non-production workpiece process components, through the intermediate entry opening into the lock chamber.

In accordance with one or more aspects of the present disclosure the lock chamber has a kinematic coupling that kinematically couples, substantially coincident with loading, the at least one interchangeable transport carrier cassette in the lock chamber, the one of the different non-production workpiece process components being deterministically set in a predetermined repeatable position by the kinematic coupling relative to a locating feature locating the sealable aperture with respect to the interior transport path.

In accordance with one or more aspects of the present disclosure the at least one interchangeable transport carrier cassette has an interchangeable cassette frame with a mating portion of the kinematic coupling deterministically coupling the interchangeable transport carrier cassette and the one of the different non-production workpiece process components carried by the interchangeable transport carrier cassette substantially coincident with loading the at least one interchangeable transport carrier cassette in the lock chamber.

In accordance with one or more aspects of the present disclosure the interchangeable cassette frame has supports connected thereto that are arranged to engage and stably hold the one of the different non-production workpiece process components carried by the interchangeable transport carrier cassette, and different interchangeable transport carrier cassettes have different supports connected to the interchangeable cassette frame, each of the different supports being arranged to engage and stably hold corresponding different non-production workpiece process components for transport with the interchangeable transport carrier cassette and in the lock chamber with the interchangeable transport carrier cassette loaded in the lock chamber.

In accordance with one or more aspects of the present disclosure the one of the different non-production workpiece process components is coupled to the interchangeable cassette frame and carried by the at least one interchangeable transport carrier cassette so as to transport the one of the different non-production workpiece process components to and from the process apparatus and repeatably position, on loading of the lock chamber through the intermediate entry opening, the one of the different non-production workpiece process components relative to a transport plane of the interior transport path so as to interface the interior transport path with the one of the different non-production workpiece process components at the repeatable position.

In accordance with one or more aspects of the present disclosure the one of the different non-production workpiece process components is interchangeably coupled to the interchangeable cassette frame with other non-production workpiece process components.

In accordance with one or more aspects of the present disclosure each of the different non-production workpiece process components is configured so as to be interchangeably carried by the interchangeable transport carrier cassette and deterministically positioned by the interchangeable transport carrier cassette loaded through the intermediate entry opening in the lock chamber.

In accordance with one or more aspects of the present disclosure the method further comprises swapping the one of the different non-production workpiece process components is from the lock chamber by swapping the at least one interchangeable transport carrier cassette in the lock chamber with another of the at least one interchangeable transport carrier cassette through the intermediate entry opening.

In accordance with one or more aspects of the present disclosure the one of the different non-production workpiece process components is a replaceable or consumable part of a process in the process section.

In accordance with one or more aspects of the present disclosure the one of the different non-production workpiece process components is a temporary shelf of the lock chamber.

In accordance with one or more aspects of the present disclosure the one of the different non-production workpiece process components is a component of a transport device configured to transport the production workpieces on the interior transport path.

In accordance with one or more aspects of the present disclosure the method further comprises deterministically coupling the at least one interchangeable transport carrier cassette to the lock chamber with a deterministic coupling connected to an interchangeable cassette frame of the at least one interchangeable transport carrier cassette, the deterministic coupling joins the interchangeable cassette frame and the lock chamber with the at least one interchangeable transport carrier cassette loaded in the lock chamber and effects, at least in part, a predetermined repeatable position of the one of the different non-production workpiece process components.

In accordance with one or more aspects of the present disclosure the deterministic coupling kinematically couples the at least one interchangeable transport carrier cassette and non-production workpiece process component in at least two orthogonal constraint axis relative to a transport plane of the interior transport path and is located in the lock chamber with the at least one interchangeable transport carrier cassette loaded in the lock chamber.

In accordance with one or more aspects of the present disclosure the deterministic coupling is sealed from an interior of the lock chamber.

In accordance with one or more aspects of the present disclosure the deterministic coupling has at least one pin dependent from the interchangeable cassette frame or the lock chamber and is configured so as to matingly engage within the lock chamber a complementing receptacle of the lock chamber or the interchangeable cassette frame, and each of the at least one pin mated to each of the complementing receptacle is sealed from an interior of the lock chamber.

In accordance with one or more aspects of the present disclosure the at least one pin includes more than one pins in a deterministic pin arrangement on the interchangeable cassette frame or the lock chamber that is positionally deterministic to the one of the different non-production workpiece process components carried by the at least one interchangeable transport carrier cassette and effects the predetermined repeatable position of the one of the different non-production workpiece process components.

In accordance with one or more aspects of the present disclosure the method further comprises interchanging the at least one interchangeable transport carrier cassette between each of the lock chamber of the process apparatus.

In accordance with one or more aspects of the present disclosure the method further comprises interchanging the at least one interchangeable transport carrier cassette between the lock chamber of the process apparatus and another sealed or unsealed chamber of the process apparatus.

In accordance with one or more aspects of the present disclosure the method further comprises interchanging the at least one interchangeable transport carrier cassette between the lock chamber of the process apparatus and another sealed or unsealed chamber of another process apparatus.

In accordance with one or more aspects of the present disclosure, the lock chamber comprises one of a metrology chamber, a load lock chamber, an inspection station, an aligner station, a buffer station, and transport chamber.

In accordance with one or more aspects of the present disclosure a process apparatus comprises:

a front end with a load opening for loading, from an exterior of the process apparatus, production workpieces into the process apparatus;

a process section with a process environment arranged for processing the production workpieces, the process section being offset at a distance from and coupled to the front end via an interior transport path configured at least for transport of the production workpieces between the front end and the process section;

a load lock between the front end and the process section with the interior transport path extending through the load lock, the load lock having, in the distance offsetting the process section from the front end, an intermediate entry with an opening shunting the interior transport path to the exterior separate from the front end; and

a removable transport carrier cassette, having a cassette frame, configured for placement into the load lock from the exterior through the intermediate entry opening, wherein the placement of the removable transport carrier cassette through the intermediate entry opening positions a transport path interface of the removeable transport carrier cassette coincident with the interior transport path.

In accordance with one or more aspects of the present disclosure a process apparatus comprises:

a load lock with an interior workpiece transport path extending through the load lock between a first valve for connection to a first atmosphere external the load lock at a first pressure and a second valve for connection to a second atmosphere external to the load lock at a lower, second pressure, the load lock having a closable entry intermediate the first and second valves with an opening to the ambient atmosphere exterior of the load lock; and

a removable transport carrier cassette, having a cassette frame, configured for placement into the load lock from the exterior through the closable entry opening, wherein the placement of the removable transport carrier cassette through the closable entry opening positions a transport path interface of the removeable transport carrier cassette coincident with the interior workpiece transport path.

In accordance with one or more aspects of the present disclosure, an interchangeable transport carrier cassette comprises:

a frame having a transport path interface; and

a handle coupled to the frame;

wherein the interchangeable transport carrier cassette that is selectable from a number of different interchangeable transport carrier cassettes, each interchangeable transport carrier cassette being selectable for entry within a lock chamber, from an exterior of the lock chamber, through an intermediate entry opening of the lock chamber, the entry and removal of the interchangeable transport carrier cassette through the intermediate entry opening loads and unloads the lock chamber with the transport path interface that interfaces, in the lock chamber, a transport path that passes into the lock chamber, coincident with the interchangeable transport carrier cassette loaded in the housing.

In accordance with one or more aspects of the present disclosure, the handle comprises an automation interface.

In accordance with one or more aspects of the present disclosure the frame includes a deterministic coupling that joins the interchangeable cassette frame and the lock chamber with the interchangeable transport carrier cassette loaded in the lock chamber and effects, at least in part, the repeatable position of the transport path interface.

In accordance with one or more aspects of the present disclosure, the deterministic coupling comprises one of pins and apertures disposed on a frame of the interchangeable transport carrier cassette that are configured to engage complimenting pins or apertures disposed on the housing.

In accordance with one or more aspects of the present disclosure, the interchangeable transport carrier cassette further comprises at least one seal coupled to the frame that circumscribes each of the one of the pins and apertures.

In accordance with one or more aspects of the present disclosure, the frame comprises supports configured to stably hold at least one non-production workpiece.

In accordance with one or more aspects of the present disclosure, the frame comprises supports configured to stably hold at least one workpiece process component.

In accordance with one or more aspects of the present disclosure, the frame forms a sealable enclosure having at least one sealable opening.

In accordance with one or more aspects of the present disclosure, the sealable enclosure is shaped and sized for entry into and coupling to the lock chamber, wherein the lock chamber includes substrate supports that are separate and distinct from the interchangeable transport carrier cassette.

In accordance with one or more aspects of the present disclosure, the frame is shaped and sized for entry into and coupling to the lock chamber, wherein the lock chamber includes substrate supports that are separate and distinct from the interchangeable transport carrier cassette.

It should be understood that the foregoing description is only illustrative of the aspects of the present disclosure. Various alternatives and modifications can be devised by those skilled in the art without departing from the aspects of the present disclosure. Accordingly, the aspects of the present disclosure are intended to embrace all such alternatives, modifications and variances that fall within the scope of any claims appended hereto. Further, the mere fact that different features are recited in mutually different dependent or independent claims does not indicate that a combination of these features cannot be advantageously used, such a combination remaining within the scope of the aspects of the present disclosure.

What is claimed is:

1. A process apparatus comprising:
a front end with a load opening for loading, from an exterior of the process apparatus, production workpieces into the process apparatus;
a process section with a process environment arranged for processing the production workpieces, the process section being offset at a distance from and coupled to the front end via an interior transport path configured at least for transport of the production workpieces between the front end and the process section;
a load lock between the front end and the process section with the interior transport path extending through the load lock, the load lock having, in the distance offsetting the process section from the front end, an intermediate entry with an opening shunting the interior transport path to the exterior separate from the front end; and
a predetermined interchangeable transport carrier cassette, having an interchangeable cassette frame, configured so as to be entered within the load lock from the exterior through the intermediate entry opening, the entry and removal of the predetermined interchangeable transport carrier cassette through the intermediate entry opening loads and unloads the load lock with a transport path interface that interfaces, in the load lock, the interior transport path coincident with the predetermined interchangeable transport carrier cassette loaded in the load lock.

2. The process apparatus of claim 1, wherein the transport path interface is a non-production workpiece process component coupled to the interchangeable cassette frame and carried by the predetermined interchangeable transport carrier cassette so as to transport the transport path interface to and from the process apparatus and repeatably position, on loading of the load lock through the intermediate entry opening, the transport path interface relative to a transport plane of the interior transport path so as to interface the interior transport path with the transport path interface at the repeatable position.

3. The process apparatus of claim 2, wherein the non-production workpiece process component is interchangeably coupled to the interchangeable cassette frame with other non-production workpiece process components.

4. The process apparatus of claim 2, wherein the non-production workpiece process component is swapped from the load lock by swapping the predetermined interchangeable transport carrier cassette in the load lock with another interchangeable transport carrier cassette through the intermediate entry opening.

5. The process apparatus of claim 2, wherein the non-production workpiece process component is a consumable of a process in the process section.

6. The process apparatus of claim 2, wherein the non-production workpiece process component is a temporary shelf of the load lock.

7. The process apparatus of claim 2, wherein the non-production workpiece process component is a component of a transport device configured to transport the production workpieces on the interior transport path.

8. The process apparatus of claim 2, further comprising a deterministic coupling connected to the interchangeable cassette frame that joins the interchangeable cassette frame and the load lock with the predetermined interchangeable transport carrier cassette loaded in the load lock and effects, at least in part, the repeatable position of the transport path interface.

9. The process apparatus of claim 8, wherein the deterministic coupling kinematically couples the predetermined interchangeable transport carrier cassette and transport path interface in at least two orthogonal constraint axis relative to the transport plane and is located in the load lock with the predetermined interchangeable transport carrier cassette loaded in the load lock.

10. The process apparatus of claim 8, wherein the deterministic coupling is sealed from an interior of the load lock.

11. The process apparatus of claim 8, wherein the deterministic coupling has at least one pin dependent from the interchangeable cassette frame or the load lock and is configured so as to matingly engage within the load lock a complementing receptacle of the load lock or the interchangeable cassette frame, and each of the at least one pin mated to each of the complementing receptacle is sealed from an interior of the load lock.

12. The process apparatus of claim 11, wherein the at least one pin includes more than one pins in a deterministic pin arrangement on the interchangeable cassette frame or the load lock that is positionally deterministic to the transport path interface carried by the predetermined interchangeable transport carrier cassette and effects the repeatable position of the transport path interface.

13. The process apparatus of claim 1, wherein the predetermined interchangeable transport carrier cassette is one or more of:
interchangeable between each of the load lock of the process apparatus,
interchangeable between the load lock of the process apparatus and another sealed or unsealed chamber of the process apparatus, and
interchangeable between the load lock of the process apparatus and another sealed or unsealed chamber of another process apparatus.

14. A process apparatus comprising:
a workpiece load chamber with a load opening for loading, from an exterior of the process apparatus, production workpieces into the process apparatus;
a process section with a process environment arranged for processing the production workpieces, the process section being offset at a distance from and coupled to the workpiece load chamber via an interior transport path configured at least for transport of the production workpieces between the load opening and process section; and
a lock chamber, between the load opening and process section, having a sealable aperture communicating with a sealed interior of the process section with the interior transport path extending through the sealable aperture of the lock chamber into the process section, the lock chamber having in the distance offsetting the process section from the workpiece load chamber, an intermediate entry with an opening shunting the interior transport path to the exterior separate from the workpiece load chamber;
wherein the lock chamber has a selectable configuration selectable through the intermediate entry opening between different predetermined configurations each having a different non-production workpiece process component within the lock chamber, the selectable configuration being effected with loading of at least one interchangeable transport carrier cassette, carrying one of the different non-production workpiece process components, through the intermediate entry opening into the lock chamber.

15. The process apparatus of claim 14, wherein the lock chamber has a kinematic coupling that kinematically couples, substantially coincident with loading, the at least one interchangeable transport carrier cassette in the lock chamber, the one of the different non-production workpiece process components being deterministically set in a predetermined repeatable position by the kinematic coupling relative to a locating feature locating the sealable aperture with respect to the interior transport path.

16. The process apparatus of claim 15, wherein the at least one interchangeable transport carrier cassette has an interchangeable cassette frame with a mating portion of the kinematic coupling deterministically coupling the interchangeable transport carrier cassette and the one of the different non-production workpiece process components carried by the interchangeable transport carrier cassette substantially coincident with loading the at least one interchangeable transport carrier cassette in the lock chamber.

17. The process apparatus of claim 16, wherein the interchangeable cassette frame has supports connected thereto that are arranged to engage and stably hold the one of the different non-production workpiece process components carried by the interchangeable transport carrier cassette, and different interchangeable transport carrier cassettes have different supports connected to the interchangeable cassette frame, each of the different supports being arranged to engage and stably hold corresponding different non-production workpiece process components for transport with the interchangeable transport carrier cassette and in the lock chamber with the interchangeable transport carrier cassette loaded in the lock chamber.

18. The process apparatus of claim 16, wherein the one of the different non-production workpiece process components is coupled to the interchangeable cassette frame and carried by the at least one interchangeable transport carrier cassette so as to transport the one of the different non-production workpiece process components to and from the process apparatus and repeatably position, on loading of the lock chamber through the intermediate entry opening, the one of the different non-production workpiece process components relative to a transport plane of the interior transport path so as to interface the interior transport path with the one of the different non-production workpiece process components at the repeatable position.

19. The process apparatus of claim 16, wherein the one of the different non-production workpiece process components is interchangeably coupled to the interchangeable cassette frame with other non-production workpiece process components.

20. The process apparatus of claim 14, wherein each of the different non-production workpiece process components is configured so as to be interchangeably carried by the interchangeable transport carrier cassette and deterministically positioned by the interchangeable transport carrier cassette loaded through the intermediate entry opening in the lock chamber.

21. The process apparatus of claim 14, wherein the one of the different non-production workpiece process components is swapped from the lock chamber by swapping the at least one interchangeable transport carrier cassette in the lock chamber with another of the at least one interchangeable transport carrier cassette through the intermediate entry opening.

22. The process apparatus of claim 14, wherein the one of the different non-production workpiece process components is a consumable of a process in the process section.

23. The process apparatus of claim 14, wherein the one of the different non-production workpiece process components is a temporary shelf of the lock chamber.

24. The process apparatus of claim 14, wherein the one of the different non-production workpiece process components is a component of a transport device configured to transport the production workpieces on the interior transport path.

25. The process apparatus of claim 14, further comprising a deterministic coupling connected to an interchangeable cassette frame of the at least one interchangeable transport carrier cassette, the deterministic coupling joins the interchangeable cassette frame and the lock chamber with the at least one interchangeable transport carrier cassette loaded in the lock chamber and effects, at least in part, a predetermined repeatable position of the one of the different non-production workpiece process components.

26. The process apparatus of claim 25, wherein the deterministic coupling kinematically couples the at least one interchangeable transport carrier cassette and non-production workpiece process component in at least two orthogonal constraint axis relative to a transport plane of the interior transport path and is located in the lock chamber with the at least one interchangeable transport carrier cassette loaded in the lock chamber.

27. The process apparatus of claim 25, wherein the deterministic coupling is sealed from an interior of the lock chamber.

28. The process apparatus of claim 25, wherein the deterministic coupling has at least one pin dependent from the interchangeable cassette frame or the lock chamber and is configured so as to matingly engage within the lock chamber a complementing receptacle of the lock chamber or the interchangeable cassette frame, and each of the at least one pin mated to each of the complementing receptacle is sealed from an interior of the lock chamber.

29. The process apparatus of claim 28, wherein the at least one pin includes more than one pins in a deterministic pin arrangement on the interchangeable cassette frame or the lock chamber that is positionally deterministic to the one of the different non-production workpiece process components carried by the at least one interchangeable transport carrier cassette and effects the predetermined repeatable position of the one of the different non-production workpiece process components.

30. The process apparatus of claim 14, wherein the at least one interchangeable transport carrier cassette is one or more of:
interchangeable between each of the lock chamber of the process apparatus,
interchangeable between the lock chamber of the process apparatus and another sealed or unsealed chamber of the process apparatus, and
interchangeable between the lock chamber of the process apparatus and another sealed or unsealed chamber of another process apparatus.

31. The process apparatus of claim 14, wherein the lock chamber comprises one of a metrology chamber, a load lock chamber, an inspection station, an aligner station, buffer station, and transport chamber.
